(19) United States
(12) Patent Application Publication
(10) Pub. No.: US 2025/0374780 A1
(43) Pub. Date: Dec. 4, 2025

(54) DISPLAY DEVICE AND ELECTRONIC DEVICE INCLUDING THE SAME

(71) Applicant: Samsung Display Co., LTD., Yongin-si, Gyeonggi-do (KR)

(72) Inventors: Dong Hee SHIN, Yongin-si (KR); Sun Kwun SON, Yongin-si (KR)

(21) Appl. No.: 19/084,672

(22) Filed: Mar. 19, 2025

(30) Foreign Application Priority Data
Jun. 3, 2024 (KR) 10-2024-0072536

(51) Int. Cl. H10K 59/131; H10K 59/35; H10K 59/60; H10K 59/88

(52) U.S. Cl. CPC H10K 59/131; H10K 59/351; H10K 59/60; H10K 59/88

(57) ABSTRACT

A display device includes: a first sub-pixel and a second sub-pixel, each including a pixel circuit; a light-sensing pixel disposed between the first sub-pixel and the second sub-pixel, the light-sensing pixel including a sensor circuit; a horizontal dummy line commonly provided in the first sub-pixel, the second sub-pixel, and the light-sensing pixel, the horizontal dummy line extending in a first direction; a first data line connected to the first sub-pixel; a second data line connected to the second sub-pixel; a readout line connected to the sensor circuit; a vertical dummy line spaced apart from the readout line; and an initialization power line supplied with an initialization power voltage. The readout line and the vertical dummy line are disposed in the same layer. The first and second data lines are disposed on the readout line and the vertical dummy line.

The application claims priority to Korean patent application No. 10-2024-0072536, filed on Jun. 3, 2024, and all the benefits accruing therefrom under 35 U.S.C. § 119, the content of which in its entirety is herein incorporated by reference.

### BACKGROUND

### 1. Field

The disclosure generally relates to a display device and an electronic device having the same.

### 2. Description of the Related Art

Recently, as interest in information displays is increased, research and development of display devices are continuously conducted.

### SUMMARY

Embodiments provide a pixel and a display device having improved reliability and an electronic device having the same.

In an embodiment of the disclosure, there is provided a display device including: a first sub-pixel and a second sub-pixel, each including a pixel circuit; a light-sensing pixel disposed between the first sub-pixel and the second sub-pixel, the light-sensing pixel including a sensor circuit; a horizontal dummy line commonly provided in the first sub-pixel, the second sub-pixel, and the light-sensing pixel, the horizontal dummy line extending in a first direction; a first data line electrically connected to the first sub-pixel; a second data line electrically connected to the second sub-pixel; a readout line electrically connected to the sensor circuit, the readout line extending in a second direction; a vertical dummy line spaced apart from the readout line; and an initialization power line supplied with an initialization power voltage, the initialization power line being electrically connected to the pixel circuit. The readout line and the vertical dummy line are disposed in a same layer, and the first and second data lines are disposed on the readout line and the vertical dummy line.

In an embodiment, in a plan view, the readout line and the vertical dummy line may be disposed between the first data line and the second data line.

In an embodiment, the vertical dummy line may be electrically separated from the horizontal dummy line.

In an embodiment, the vertical dummy line may be electrically connected to the initialization power line.

In an embodiment, the initialization power line may extend in the first direction, and the vertical dummy line may extend in the second direction to form a mesh structure.

In an embodiment, the display device may further include: a third sub-pixel and a fourth sub-pixel, disposed adjacent to the second sub-pixel in the first direction; a third data line electrically connected to the third sub-pixel; a fourth data line electrically connected to the fourth sub-pixel; and an additional line disposed between the third sub-pixel and the fourth sub-pixel. The additional line may be disposed in a same layer as the first to fourth data lines.

In an embodiment, the additional line may be electrically connected to the initialization power line.

In an embodiment, the additional line and the readout line may be disposed in different layers.

In an embodiment, in a plan view, the additional line may be disposed between the third data line and the fourth data line.

In an embodiment, in the plan view, the pixel circuit of the first sub-pixel may be disposed between the first data line and the sensor circuit, and the pixel circuit of the second sub-pixel may be disposed between the second data line and the sensor circuit.

In the plan view, a pixel circuit of the third sub-pixel may be disposed between the third data line and the additional line, and a pixel circuit of the fourth sub-pixel may be disposed between the additional line and the fourth data line.

In an embodiment, the vertical dummy line may be electrically connected to the horizontal dummy line.

In an embodiment, the vertical dummy line and the horizontal dummy line may be supplied with a low-potential driving voltage having a constant level.

In an embodiment, the horizontal dummy line may extend in the first direction, and the vertical dummy line may extend in the second direction to have a mesh structure.

In an embodiment, each of the first sub-pixel and the second sub-pixel may include a light-emitting element emitting light. The light-sensing pixel may include a light-receiving element outputting a sensing signal.

In an embodiment, the display device may further include: first, second, third, fourth, fifth, sixth, seventh, eighth, and ninth insulating layers sequentially disposed on a substrate; a first conductive layer disposed between the second insulating layer and the third insulating layer; a second conductive layer disposed between the third insulating layer and the fourth insulating layer; a third conductive layer disposed between the fifth insulating layer and the sixth insulating layer; a fourth conductive layer disposed between the sixth insulating layer and the seventh insulating layer; a fifth conductive layer disposed between the seventh insulating layer and the eighth insulating layer; and a sixth conductive layer disposed between the eighth insulating layer and the ninth insulating layer. The second conductive layer may include the horizontal dummy line, the fourth conductive layer may include the initialization power line, the fifth conductive layer may include the readout line and the vertical dummy line, and the sixth conductive layer may include the first and second data lines.

In an embodiment of the disclosure, there is provided a display device including: a first sub-pixel, a second sub-pixel, a third sub-pixel, and a fourth sub-pixel, each including a pixel circuit, the first sub-pixel, the second sub-pixel, the third sub-pixel, and the fourth sub-pixel, being arranged in a first direction; a light-sensing pixel disposed between the first sub-pixel and the second sub-pixel, the light-sensing pixel including a sensor circuit; a horizontal dummy line commonly provided in the first to fourth sub-pixels and the light-sensing pixel, the horizontal dummy line extending in the first direction; a first data line electrically connected to the pixel circuit of the first sub-pixel; a second data line electrically connected to the pixel circuit of the second sub-pixel; a third data line electrically connected to the pixel circuit of the third sub-pixel; a fourth data line electrically connected to the pixel circuit of the fourth sub-pixel; a readout line electrically connected to the sensor circuit, the readout line extending in a second direction; a vertical dummy line spaced apart from the readout line; an initialization power line supplied with an initialization voltage, the initialization power line being electrically connected to the pixel circuit; and an additional line disposed between the third sub-pixel and the fourth sub-pixel, the additional line being electrically connected to the initialization power line. In a plan view, the vertical dummy line is disposed between the first data line and the second data line, and the additional line is disposed between the third data line and the fourth data line, and the vertical dummy line and the readout line are disposed in a same layer.

In an embodiment, the vertical dummy line may be electrically connected to the initialization power line, and be electrically separated from the horizontal dummy line.

In an embodiment, the vertical dummy line may be electrically connected to the horizontal dummy line, and be electrically separated from the initialization power line.

In an embodiment of the disclosure, there is provided an electronic device including: a processor which provides input image data to a display device; and the display device which displays an image, based on the input image data. The display device includes: a first sub-pixel and a second sub-pixel, each including a pixel circuit; a light-sensing pixel disposed between the first sub-pixel and the second sub-pixel, the light-sensing pixel including a sensor circuit; a horizontal dummy line commonly provided in the first sub-pixel, the second sub-pixel, and the light-sensing pixel, the horizontal dummy line extending in a first direction; a first data line electrically connected to the first sub-pixel; a second data line electrically connected to the second sub-pixel; a readout line electrically connected to the sensor circuit, the readout line extending in a second direction; a vertical dummy line spaced apart from the readout line; and an initialization power line supplied with an initialization power voltage, the initialization power line being electrically connected to the pixel circuit, the readout line and the vertical dummy line are disposed in a same layer, and the first and second data lines are disposed on the readout line and the vertical dummy line.

In an embodiment, in a plan view, the readout line and the vertical dummy line may be disposed between the first data line and the second data line.

### BRIEF DESCRIPTION OF THE DRAWINGS

Embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey the scope of the embodiments to those skilled in the art.

In the drawing figures, dimensions may be exaggerated for clarity of illustration. It will be understood that when an element is also referred to as being “between” two elements, it may be the only element between the two elements, or one or more intervening elements may also be present. Like reference numerals refer to like elements throughout.

FIG. 1 is a schematic block diagram illustrating an embodiment of a display device in accordance with the disclosure.

FIG. 2 is a schematic block diagram illustrating an embodiment of the display device shown in FIG. 1.

FIGS. 3 and 4 are schematic diagrams illustrating an embodiment of an arrangement of pixel circuits and sensor circuits of a display area of a display panel included in the display device shown in FIG. 2.

FIG. 5 is a schematic diagram illustrating an embodiment of the display area of the display panel included in the display device shown in FIG. 2.

FIG. 6 is a schematic circuit diagram illustrating an embodiment of a sub-pixel and a light-sensing pixel, which are included in a display area shown in FIG. 1.

FIG. 7 is a schematic cross-sectional view illustrating an embodiment of one area of a display device in accordance with the disclosure.

FIG. 8 is a schematic cross-sectional view illustrating a reflection path of light in the display device shown in FIG. 7.

FIG. 9 is a schematic plan view illustrating an embodiment of sub-pixels and a first light-sensing pixel in accordance with the disclosure.

FIG. 10 is a schematic plan view illustrating only first, second, fifth, sixth, seventh, eighth, ninth, and eleventh transistors and components included in a first conductive layer in FIG. 9.

FIG. 11 is a schematic plan view illustrating only components included in a second conductive layer in FIG. 9.

FIG. 12 is a schematic plan view illustrating only third, fourth, and tenth transistors and components included in a third conductive layer in FIG. 9.

FIG. 13 is a schematic plan view illustrating only component included in a fourth conductive layer in FIG. 9.

FIG. 14 is a schematic plan view illustrating only component included in a fifth conductive layer in FIG. 9.

FIG. 15 is a schematic plan view illustrating only component included in a sixth conductive layer in FIG. 9.

FIG. 16 is a schematic plan view illustrating only components included in the fourth conductive layer, the fifth conductive layer, and the sixth conductive layer in

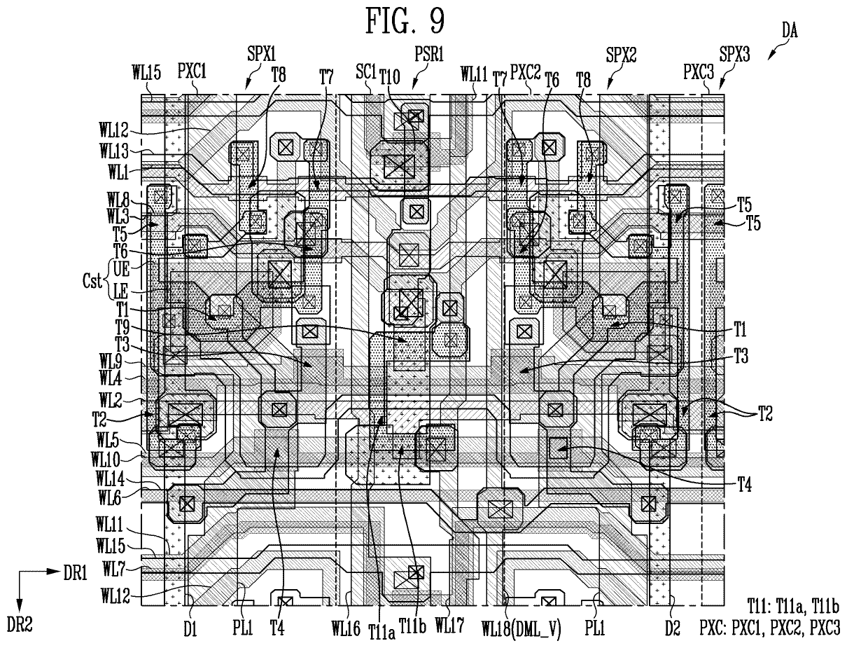

FIG. 9.

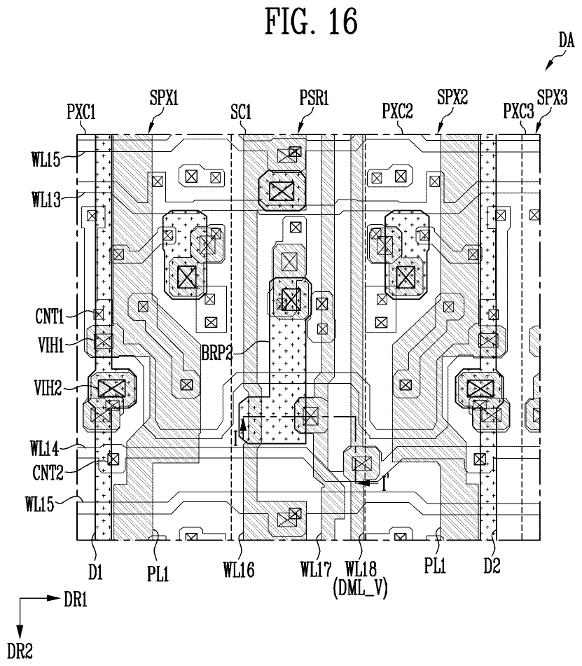

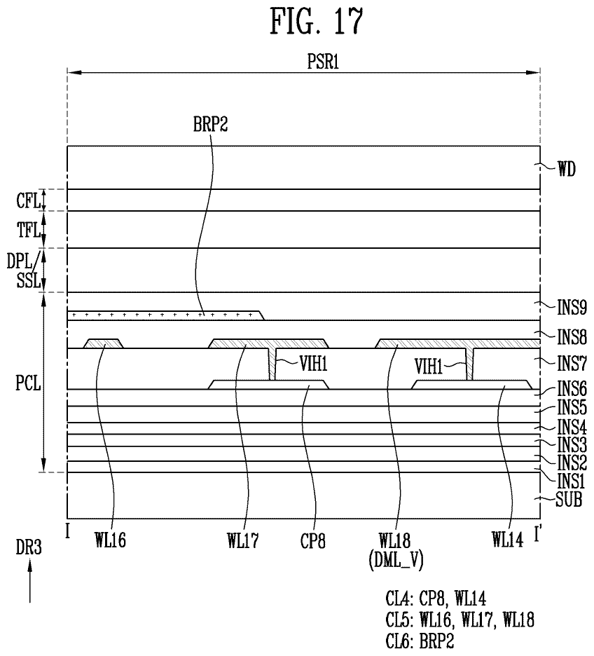

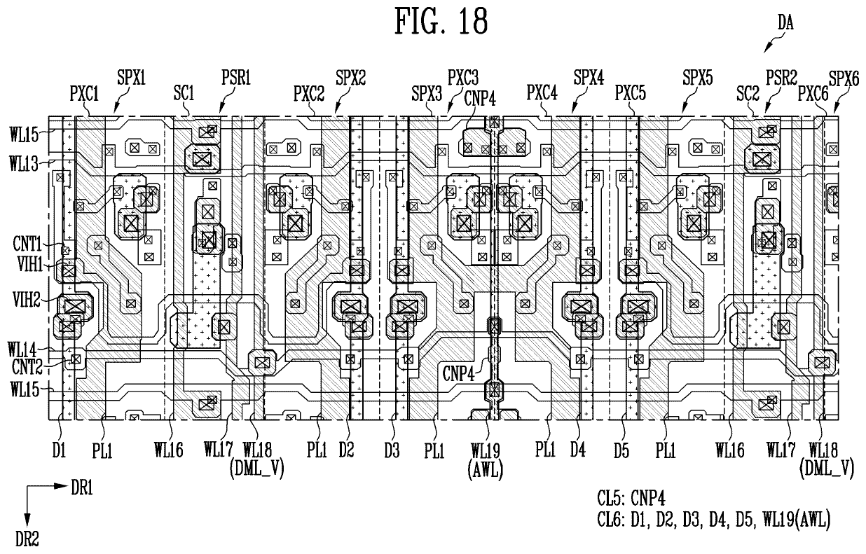

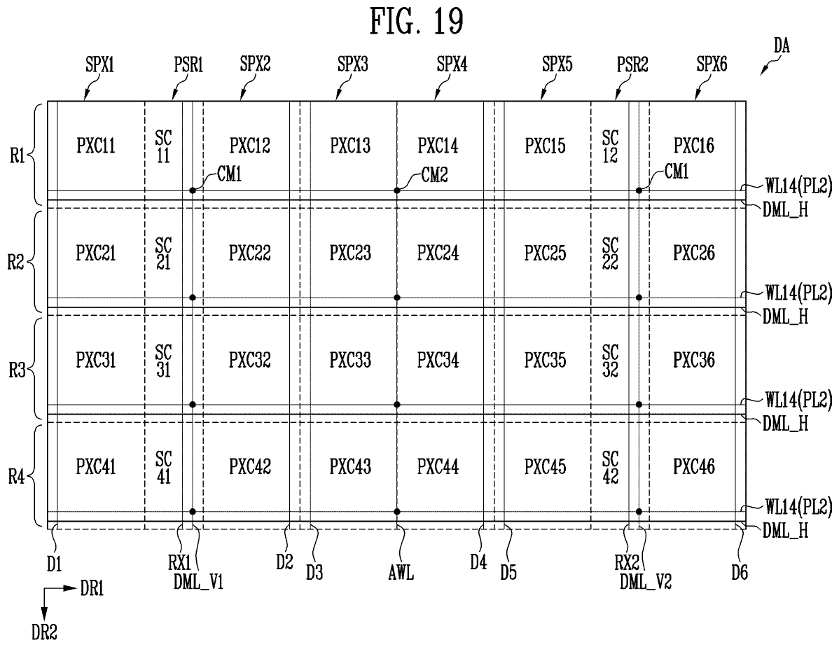

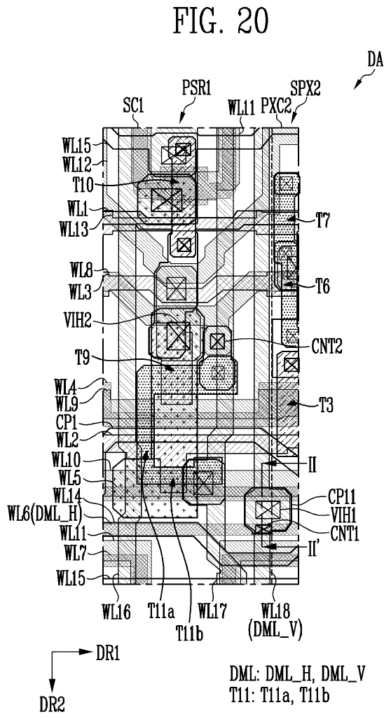

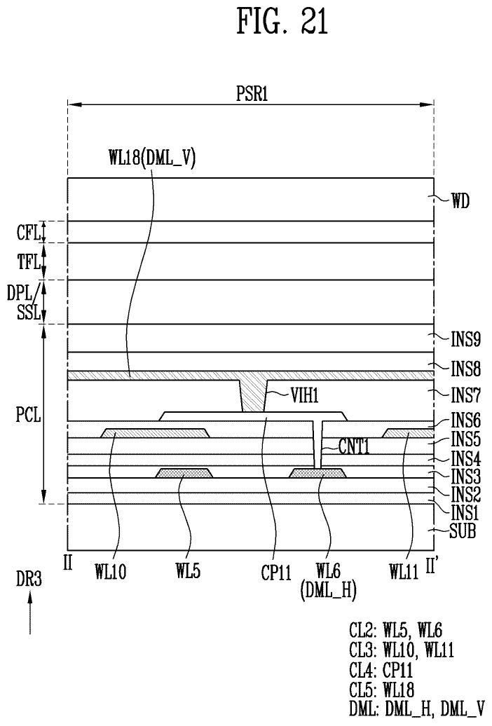

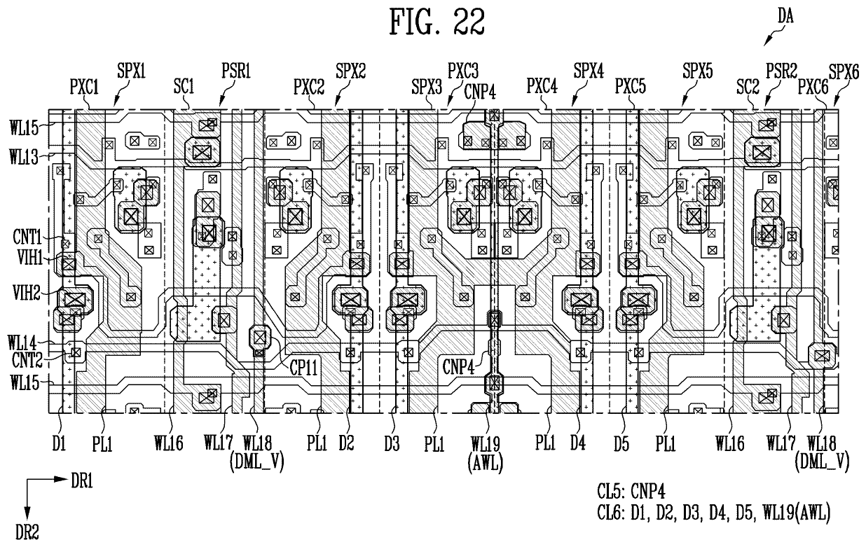

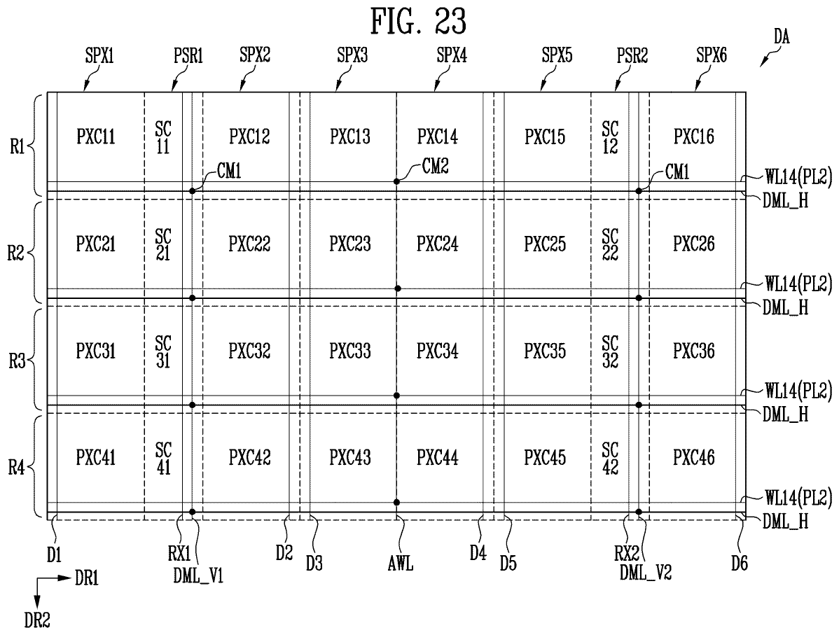

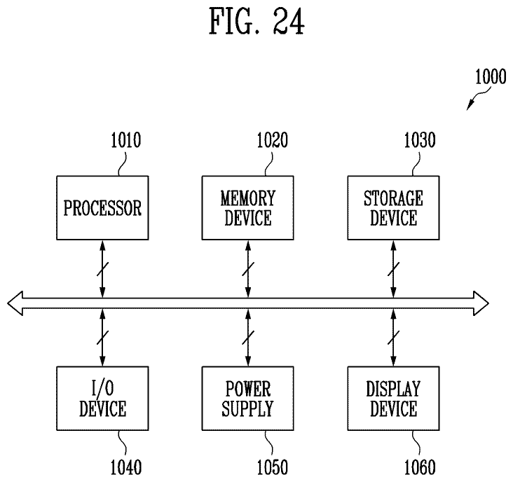

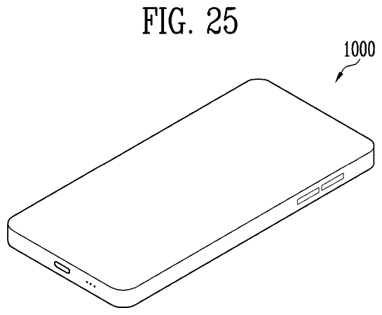

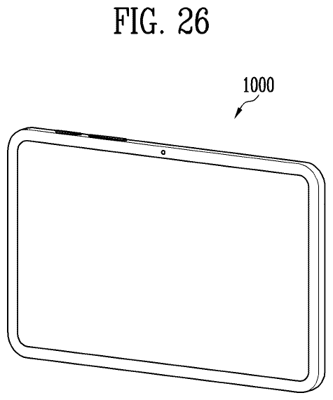

FIG. 17 is a schematic cross-sectional view taken along line I-I′ shown in FIG. 16.

FIG. 18 is a schematic plan view illustrating an embodiment of sub-pixels and light-sensing pixels, which are disposed in one area of a display area of a display device in accordance with the disclosure.

FIG. 19 is a schematic diagram illustrating an embodiment of a connection relationship of some lines in one area of a display area of a display device in accordance with the disclosure.

FIG. 20 is a schematic plan view illustrating an embodiment of a first light-sensing pixel disposed in one area of a display area of a display device in accordance with the disclosure.

FIG. 21 is a schematic cross-sectional view taken along line II-II′ shown in FIG. 20.

FIG. 22 is a schematic plan view illustrating an embodiment of sub-pixels and light-sensing pixels, which are disposed in one area of a display area of a display device in accordance with the disclosure.

FIG. 23 is a schematic diagram illustrating an embodiment of a connection relationship of some lines in one area of a display area of a display device in accordance with the disclosure.

FIG. 24 is a schematic block diagram illustrating an embodiment of an electronic device in accordance with the disclosure.

FIG. 25 is a schematic view illustrating an embodiment in which the electronic device shown in FIG. 24 is implemented as a smartphone.

FIG. 26 is a schematic view illustrating an embodiment in which the electronic device shown in FIG. 24 is implemented as a tablet personal computer (“PC”).

### DETAILED DESCRIPTION

The disclosure may apply various changes and different shape, therefore only illustrate in details with particular examples. However, the examples do not limit to predetermined shapes but apply to all the change and equivalent material and replacement. The drawings included are illustrated a fashion where the drawing figures are expanded for the better understanding.

Like numbers refer to like elements throughout. In the drawings, the thickness of certain lines, layers, components, elements or features may be exaggerated for clarity. It will be understood that, although the terms “first,” “second,” etc. may be used herein to describe various elements, these elements should not be limited by these terms. These terms are only used to distinguish one element from another element. Thus, a “first” element discussed below could also be termed a “second” element without departing from the teachings of the disclosure. As used herein, the singular forms are intended to include the plural forms as well, unless the context clearly indicates otherwise.

It will be further understood that the terms “includes” and/or “including,” when used in this specification, specify the presence of stated features, integers, steps, operations, elements, and/or components, but do not preclude the presence and/or addition of one or more other features, integers, steps, operations, elements, components, and/or groups thereof. Further, an expression that an element such as a layer, region, substrate or plate is placed “on” or “above” another element indicates not only a case where the element is placed “directly on” or “just above” the other element but also a case where a further element is interposed between the element and the other element. On the contrary, an expression that an element such as a layer, region, substrate or plate is placed “beneath” or “below” another element indicates not only a case where the element is placed “directly beneath” or “just below” the other element but also a case where a further element is interposed between the element and the other element.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). The term “about” can mean within one or more standard deviations, or within ±30%, 20%, 10%, 5% of the stated value, for example.

Hereinafter, embodiments of the disclosure and items desired for those skilled in the art to easily understand the content of the disclosure will be described in detail with reference to the accompanying drawings. In the following description, singular forms in the disclosure are intended to include the plural forms as well, unless the context clearly indicates otherwise.

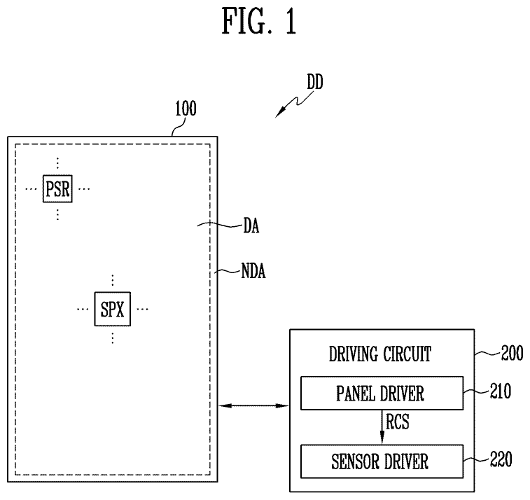

FIG. 1 is a schematic block diagram illustrating an embodiment of a display device DD in accordance with the disclosure.

Referring to FIG. 1, the display device DD in the embodiments of the disclosure may include a display panel 100 and a driving circuit 200. In embodiments, the driving circuit 200 may include a panel driver 210 and a sensor driver 220.

The display device DD may be implemented as a self-luminous display device including a plurality of self-luminous elements. In an embodiment, the display device DD may be an organic light-emitting display device including an organic light-emitting element, for example. However, the disclosure is not limited thereto, and the display device DD may be implemented as a display device including an inorganic light-emitting element, a display device including light-emitting elements configured with a combination of an inorganic material and an organic material, a display device which displays an image, using a quantum dot, or the like.

The display device DD may be a flat panel display device, a flexible display device, a curved display device, a foldable display device, a bendable display device, or a rollable display device. Also, the display device DD may be applied to a transparent display device, a head-mounted display device, a wearable display device, or the like.

The display panel 100 may include a display area DA and a non-display area NDA. The display area DA may be an area in which at least one sub-pixel SPX (or pixel) is provided. The sub-pixel SPX may include at least one light-emitting element. In an embodiment, the light-emitting element may include a light-emitting layer (e.g., an organic light-emitting layer), for example. A portion at which light is emitted by the light-emitting element may be defined as an emission area. The display device DD may drive the sub-pixel SPX, thereby displaying an image in the display area DA.

The non-display area NDA may be an area provided at the periphery of the display area DA. In embodiments, the non-display area NDA may inclusively mean the other area except the display area DA on the display panel 100. In an embodiment, the non-display area NDA may include a line area, a pad area, various dummy areas, or the like, for example.

At least one light-sensing pixel PSR may be included in the display area DA. The light-sensing pixel PSR may be also referred to as a photo sensor. The light-sensing pixel PSR may include a light-receiving element including a light-receiving layer. The light-receiving layer of the light-receiving element may be disposed while being spaced apart from the light-emitting layer of the light-emitting element in the display area DA.

A plurality of light-sensing pixels PSR may be distributed while being spaced apart from each other throughout the entirety of the area of the display area DA. However, the disclosure is not limited thereto. Only one area of the display area DA may be set as a predetermined sensing area, and light-sensing pixels PSR may be provided in the corresponding sensing area. Light-sensing pixels PSR may be provided in at least a portion of the non-display area NDA.

The light-sensing pixel PSR may sense that light output from a light source (e.g., the light-emitting element of the sub-pixel SPX) is reflected by an external object (e.g., a finger of a user, or the like). In an embodiment, a fingerprint of the user may be sensed through the light-sensing pixel PSR, for example. Hereinafter, a case where the light-sensing pixel PSR is used for fingerprint sensing will be described as an example. However, in various embodiments, the light-sensing pixel PSR may sense various biometric information such as an iris and a vein.

The driving circuit 200 may include the panel driver 210 and the sensor driver 220. The panel driver 210 and the sensor driver 220 may be implemented as integrated circuits independent from each other. In some embodiments, the driving circuit 200 may be implemented as one integrated circuit. At least a portion of the sensor driver 220 may be included in the panel driver 210, or operate in connection with the panel driver 210.

The panel driver 210 may scan the sub-pixel SPX of the display area DA, and supply, to the sub-pixel SPX, a data signal corresponding to image data (or an image). The display panel 100 may display an image corresponding to the data signal.

The panel driver 210 may supply a driving signal for light-sensing (e.g., fingerprint sensing) to the sub-pixel SPX. The driving signal may be provided to allow the sub-pixel SPX to emit light, thereby operating as a light source for the light-sensing pixel PSR. The panel driver 210 may supply the driving signal for light-sensing and/or another driving signal to the light-sensing pixel PSR. However, the disclosure is not limited thereto, and driving signals for light-sensing may be supplied to the light-sensing pixel PSR by the sensor driver 220.

The sensor driver 220 may detect biometric information such as a finger of the user, based on a sensing signal received from the light-sensing pixel PSR. In some embodiments, the sensor driver 220 may supply the driving signals to the light-sensing pixel PSR and/or the sub-pixel SPX.

The panel driver 210 may provide a readout control signal to the sensor driver 220, and the sensor driver 220 may read out (or sample) a sensing signal in connection with the panel driver 210, based on the readout control signal RCS. In an embodiment, the sensor driver 220 may read out or sample the sensing signal in at least one pixel row (or horizontal line) unit in response to the readout control signal RCS, for example.

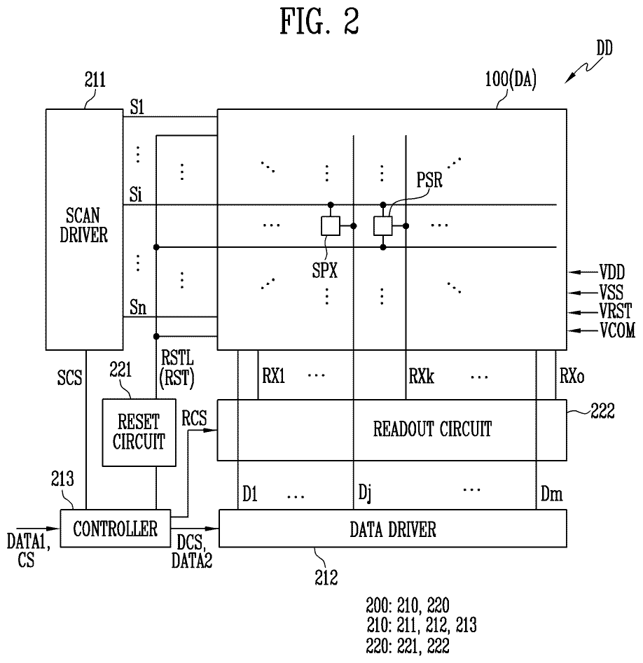

FIG. 2 is a schematic block diagram illustrating an embodiment of the display device DD shown in FIG. 1.

Referring to FIGS. 1 and 2, the display device DD may include a display panel 100 and a driving circuit 200.

The display panel 100 may include signal lines, sub-pixels SPX, and light-sensing pixels PSR. The signal lines may include scan lines S1 to Sn, data lines D1 to Dm, readout lines RX1 to RXo, and a reset line RSTL (or reset control line) (each of n, m, and o may be a natural number).

The sub-pixels SPX may be disposed or disposed in areas (e.g., pixel areas) partitioned by the scan lines S1 to Sn and the data lines D1 to Dm. The light-sensing pixels PSR may be disposed or disposed in areas partitioned by the scan lines S1 to Sn and the readout lines RX1 to RXo. The sub-pixels SPX and the light-sensing pixels PSR may be arranged in a two-dimensional array in a display area DA of the display panel 100, but the disclosure is not limited thereto.

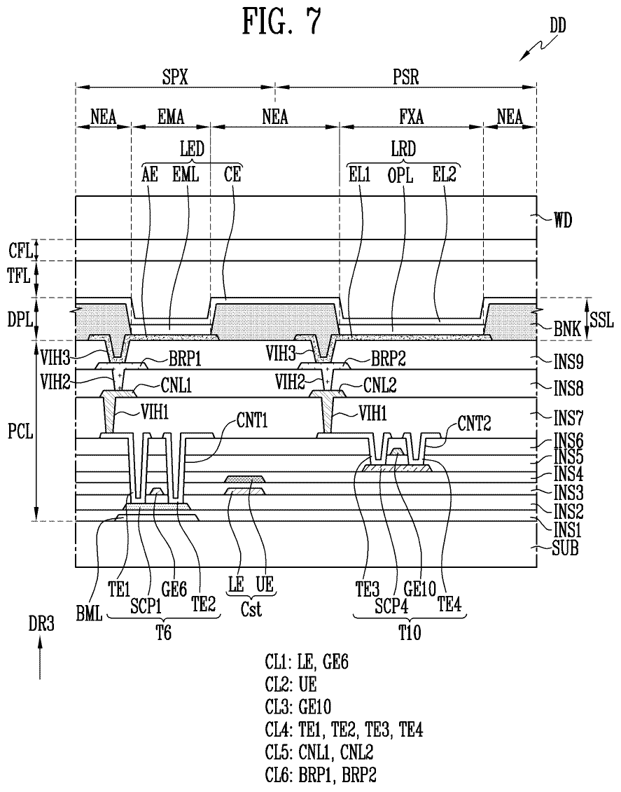

The sub-pixel SPX may be electrically connected to at least one of the scan lines S1 to Sn and at least one of the data lines D1 to Dm. The light-sensing pixel PSR may be electrically connected to one of the scan lines S1 to Sn, one of the readout lines RX1 to RXo, and the reset line RSTL. A connection configuration between the sub-pixel SPX, the light-sensing pixel PSR, and the signal lines will be described later with reference to FIG. 7.

Power voltages VDD, VSS, VRST, and VCOM desired for driving of the sub-pixel SPX and the light-sensing pixel PSR may be provided to the display panel 100. The power voltages VDD, VSS, VRST, and VCOM may be supplied from a power supply. The power supply may be implemented as a power management integrated circuit (“PMIC”).

The driving circuit 200 may include a scan driver 211, a data driver 212, a controller 213, a reset circuit 221, and a readout circuit 222. In an embodiment, the scan driver 211, the data driver 212, and the controller 213 may be included in a panel driver 210, and the reset circuit 221 and the readout circuit 222 may be included in a sensor driver 220, for example. However, the disclosure is not limited thereto. In some embodiments, the reset circuit 221 may be included in the panel driver 210.

The scan driver 211 may be electrically connected to the sub-pixels SPX and the light-sensing pixels PSR through the scan lines S1 to Sn. The scan driver 211 may generate scan signals, based on a scan control signal SCS, and supply the scan signal to the scan lines S1 to Sn. The scan control signal SCS may include a start signal, clock signals, or the like, and be provided from the controller 213 to the scan driver 211. In an embodiment, the scan driver 211 may be implemented as a shift register which generates and outputs scan signals by sequentially shifting the start signal in a pulse form, using the clock signals, for example. The scan driver 211 may selectively drive the sub-pixel SPX and the light-sensing pixel PSR while scanning the display panel 100.

The scan driver 211 may be formed together with the sub-pixels SPX of the display panel 100, but the disclosure is not limited thereto. In some embodiments, the scan driver 211 may be implemented as an integrated circuit.

A sub-pixel SPX selectively driven by the scan driver 211 may emit light with a luminance corresponding to a data signal provided to a corresponding data line among the data lines D1 to Dm. The light-sensing pixel PSR selectively driven by the scan driver 211 may output, to a corresponding readout line, an electrical signal (e.g., a sensing signal) corresponding to sensed light. In an embodiment, a sub-pixel SPX selectively driven through an ith scan line Si may emit light with a luminance corresponding to a data signal supplied to a jth data line Dj (i and j are natural numbers equal to or less than n and m, respectively), for example. In an embodiment, a light-sensing pixel PSR selectively driven through the ith scan line Si may output an electrical signal corresponding to sensed light to a kth readout line RXk (k is a natural number equal to or less than o), for example.

The data driver 212 may generate a data signal (or data voltage), based on image data DATA2 and a data control signal DCS, which are provided from the controller 213, and supply the data signal to the display panel 100 (or the sub-pixels SPX) through the data lines D1 to Dm. The data control signal DCS may be a signal for controlling an operation of the data driver 212, and include a horizontal start signal, a data clock signal, or the like. In an embodiment, the data driver 212 may include a shift register which generates a sampling signal by shifting the horizontal start signal in synchronization with the data clock signal, a latch which latches the image data DATA2 in response to the sampling signal, a digital-analog converter (or decoder) which converts the latched image data (e.g., data in a digital form) into a data signal in an analog form, and a buffer (or amplifier) which outputs the data signal to a corresponding data line (e.g., the jth data line Dj), for example.

The controller 213 may receive input image data DATA1 and a control signal CS from an external device (e.g., a graphic processor, an application processor, or a first processor), generate the scan control signal SCS and the data control signal DCS, based on the control signal CS, and generate the image data DATA2 by converting the input image data DATA1. The control signal CS may include a vertical synchronization signal, a horizontal synchronization signal, a reference clock signal, or the like. The vertical synchronization signal may represent a start of frame data (i.e., data corresponding to a frame period in which one frame image is displayed), and the horizontal synchronization signal may represent a start of a data row (i.e., one data row among a plurality of data rows included in frame data). The controller 213 may convert the input image data DATA1 into the image data DATA2 having a format corresponding to a pixel arrangement in the display panel 100.

Also, the controller 213 may generate a reset control signal and a readout control signal RCS, based on the control signal CS.

The reset circuit 221 may be commonly connected to all the light-sensing pixels PSR provided in the display panel 100 through one reset line RSTL. The reset circuit 221 may simultaneously supply a reset signal RST to all the light-sensing pixels PSR in response to the reset control signal. Since the reset signal RST is simultaneously supplied to all the light-sensing pixels PSR, the reset signal RST may be also referred to as a global reset signal.

The readout circuit 222 may receive a sensing signal from the light-sensing pixel PSR through the readout lines RX1 to RXo, and perform signal processing on the sensing signal.

In an embodiment, the readout circuit 222 may perform a correlated double sampling (“CDS”) operation for removing noise from a sensing signal provided from the light-sensing pixel PSR, for example. A timing of the CDS operation of the readout circuit 222 may be determined by the readout control signal RCS. The readout circuit 222 may convert the sensing signal in an analog form into a signal (or digital value) in a digital form. A configuration for CDS and analog-digital conversion may be provided with respect to the readout lines RX1 to RXo, and the readout circuit 222 may process, in parallel, sensing signals provided from the readout lines RX1 to RXo.

The processed sensing signals, i.e., readout sensing signals may be transferred as one sensing data (or biometric information) to an external device (e.g., an application processor), and biometric authentication (e.g., fingerprint authentication or the like) may be performed based on the sensing data. In some embodiments, the readout sensing signals may be supplied to the controller 213, and the biometric authentication may be performed in the controller 213.

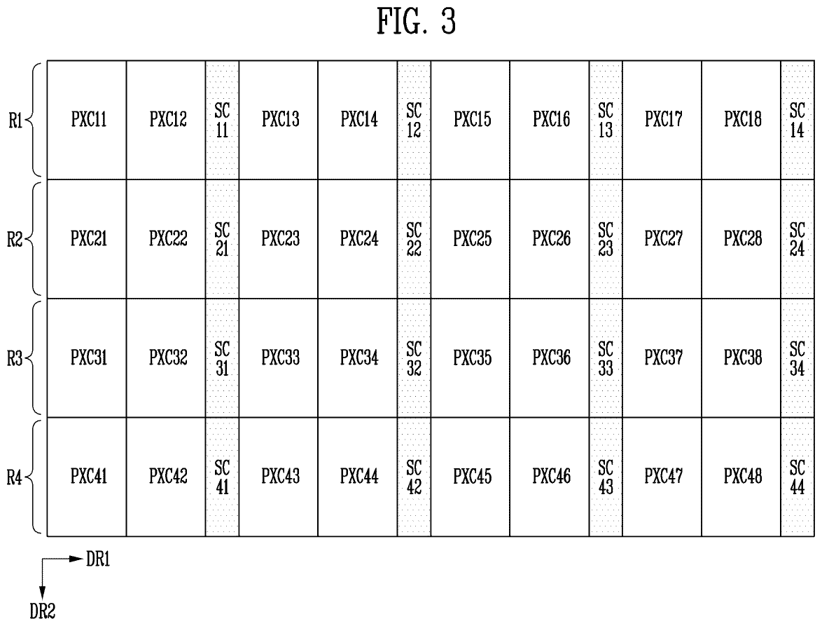

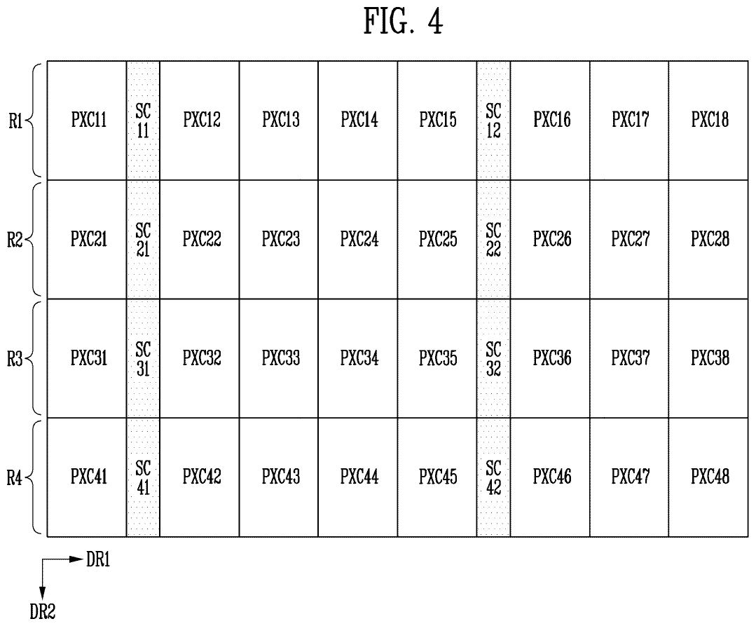

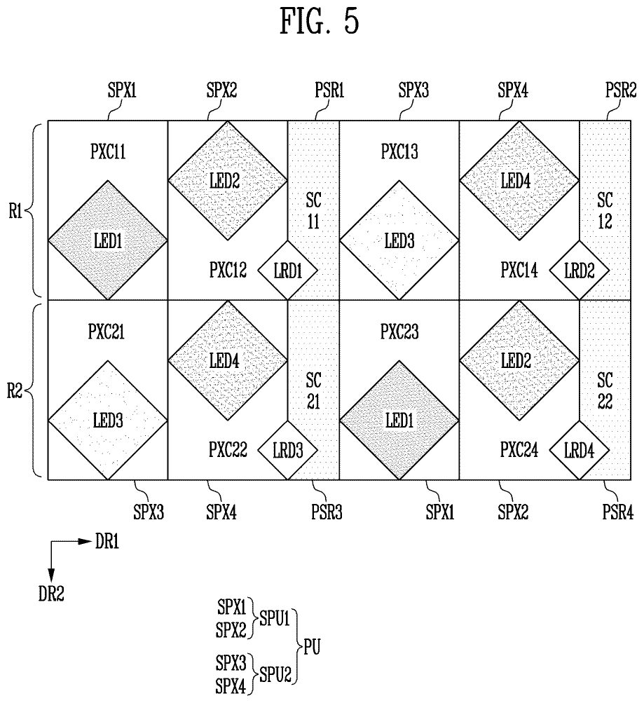

FIGS. 3 and 4 are schematic diagrams illustrating an embodiment of an arrangement of pixel circuits and sensor circuits of the display area of the display panel included in the display device shown in FIG. 2. FIG. 5 is a schematic diagram illustrating an embodiment of the display area of the display panel included in the display device shown in FIG. 2.

Embodiments shown in FIG. 4 illustrates a modified example shown in FIG. 3 in relation to a number or the like of pixel circuits disposed between two sensor circuits adjacent to each other.

Referring to FIGS. 1 to 5, sub-pixels SPX1 to SPX4 and a plurality of light-sensing pixels PSR1 to PSR4 may be disposed in the display area DA of the display panel 100.

The display area DA may be divided into pixel rows R1 to R4. Each of the pixel rows R1 to R4 may extend in a first direction DR1, and be arranged in a second direction DR2. Each of the pixel rows R1 to R4 may include sub-pixels SPX1 to SPX4. Each of the sub-pixels SPX1 to SPX4 may include one of pixel circuits PXC11 to PXC48 and one of light-emitting elements LED1 to LED4.

In embodiments, a first sub-pixel SPX1, a second sub-pixel SPX2, and a third sub-pixel SPX3 may emit light of a first color, light of a second color, and light of a third color, respectively. The light of the first color, the light of the second color, and the light of the third color may be lights of different colors. Each of the light of the first color, the light of the second color, and the light of the third color may be one of red light, green light, and blue light. A first light-emitting element LED1 emitting the light of the first color may be disposed in the first sub-pixel SPX1, a second light-emitting element LED2 emitting the light of the second color may be disposed in the second sub-pixel SPX2, a third light-emitting element LED3 emitting the light of the third color may be disposed in the third sub-pixel SPX3, and a fourth light-emitting element LED4 emitting the light of the second color may be disposed in a fourth sub-pixel SPX4. The second light-emitting element LED2 and the fourth light-emitting element LED4 may emit light of the same color.

In FIG. 5, each of the light-emitting elements LED1 to LED4 may be understood as an emission area corresponding to a light-emitting layer. However, this is for convenience of description, and the color of light emitted by each of the light-emitting elements LED1 to LED4 and the position, area, shape, or the like of each of the light-emitting elements LED1 to LED4, or the like are not be limited thereto.

In embodiments, sub-pixels SPX1 to SPX4 may be arranged with respect to the first direction DR1 in an order of a first sub-pixel SPX1 emitting red light, a second sub-pixel SPX2 emitting green light, a third sub-pixel SPX3 emitting blue light, and a fourth sub-pixel SPX4 emitting green light on each of odd-numbered pixel rows including a first pixel row R1 (or first horizontal line) and a third pixel row R3 (or third horizontal line).

Sub-pixels SPX1 to SPX4 may be arranged with respect to the first direction DR1 in an order of a third sub-pixel SPX3, a fourth sub-pixel SPX4, a first sub-pixel SPx1, and a second sub-pixel SPX2 on each of even-numbered pixel rows including a second pixel row R2 (or second horizontal line) and a fourth pixel row R4 (or fourth horizontal line).

In embodiments, the first sub-pixel SPX1 and the second sub-pixel SPX2 may constitute a first sub-pixel unit SPU1, and the third sub-pixel SPX3 and the fourth sub-pixel SPX4 may constitute a second sub-pixel unit SPU2. The first sub-pixel unit SPU1 and the second sub-pixel unit SPU2 may be alternately disposed on the odd-numbered pixel rows R1 and R3, and the second sub-pixel unit SPU2 and the first sub-pixel unit SPU1 may be alternately disposed on the even-numbered pixel rows R2 and R4 on the contrary to the odd-numbered pixel rows R1 and R3.

It may be understood that predetermined first and second sub-pixel units SPU1 and SPU2 adjacent to each other constitute one pixel unit PU. In an embodiment, FIG. 5 illustrates a pixel unit PU of each of the first pixel row R1 and the second pixel row R2, for example. However, the disclosure is not limited thereto, and the arrangement of sub-pixels SPX1 to SPX4 may be variously changed.

Pixel circuits PXC11 to PXC18 respectively corresponding to sub-pixels SPX1 to SPX4 of the first pixel row R1 may be arranged in the first direction DR1 on the first pixel row R1. Pixel circuits PXC21 to PXC28 respectively corresponding to sub-pixels SPX1 to SPX4 of the second pixel row R2 may be arranged in the first direction DR1 on the second pixel row R2. Pixel circuits PXC31 to PXC38 respectively corresponding to sub-pixels SPX1 to SPX4 of the third pixel row R3 may be arranged in the first direction DR1 on the third pixel row R3. Pixel circuits PXC41 to PXC48 respectively corresponding to sub-pixels SPX1 to SPX4 of the fourth pixel row R4 may be arranged in the first direction DR1 on the fourth pixel row R4.

In FIG. 3, first, second, third, and fourth pixel circuits PXC11, PXC12, PXC13, and PXC14 of the first pixel row R1 may be included in one pixel unit PU, and fifth, sixth, seventh, and eighth pixel circuits PXC15, PXC16, PXC17, and PXC18 of the first pixel row R1 may be included in another pixel unit PU.

Similarly to this, first to fourth pixel circuits PXC21 to PXC24 of the second pixel row R2, fifth to eighth pixel circuits PXC25 to PXC28 of the second pixel row R2, first to fourth pixel circuits PXC31 to PXC34 of the third pixel row R3, fifth to eighth pixel circuits PXC35 to PXC38 of the third pixel row R3, first to fourth pixel circuits PXC41 to PXC44 of the fourth pixel row R4, and fifth to eighth pixel circuits PXC45 to PXC48 of the fourth pixel row R4 may also be included in different pixel units PU.

In embodiments, the pixel rows R1 to R4 may include light-receiving elements LRD1 to LRD4. In FIG. 5, each of the light-receiving elements LRD1 to LRD4 may be understood as a light-receiving area corresponding to a light-receiving layer. However, this is for convenience of description, and the position, area, shape, or the like of each of the light-receiving elements LRD1 to LRD4 may be variously changed.

Light-receiving elements LRD1 and LRD2 of the first pixel row R1 may overlap with at least portions of the pixel circuits PXC11 to PXC14 of the first pixel row R1 and sensor circuits SC11 and SC12 of the first pixel row R1, respectively. Light-receiving elements LRD3 and LRD4 of the second pixel row R2 may overlap with at least portions of the pixel circuits PXC21 to PXC24 of the second pixel row R2 and sensor circuits SC21 and SC22 of the second pixel row R2, respectively.

In embodiments, a first light-receiving element LRD1 may overlap with at least a portion of a first sensor circuit SC11 of the first pixel row R1, and a third light-receiving element LRD3 may overlap with at least a portion of a first sensor circuit SC21 of the second pixel row R2.

In addition, a second light-receiving element LRD2 may overlap with at least a portion of a second sensor circuit SC12 of the first pixel row R1, and a fourth light-receiving element LRD4 may overlap with at least a portion of a second sensor circuit SC22 of the second pixel row R2.

In embodiments, each of sensor circuits SC11 to SC44 may be electrically connected to a corresponding light-receiving element. The first sensor circuit SC11 of the first pixel row R1 may be electrically connected to the first light-receiving element LRD1 to constitute a first light-sensing pixel PSR1. That is, the first sensor circuit SC11 and the first light-emitting element LRD1 may constitute the first light-sensing pixel PSR1. The second sensor circuit SC12 of the first pixel row R1 may be electrically connected to the second light-receiving element LRD2 to constitute a second light-sensing pixel PSR2. That is, the second sensor circuit SC12 and the second light-receiving element LRD2 may constitute the second light-sensing pixel PSR2. The first sensor circuit SC21 of the second pixel row R2 may be electrically connected to the third light-receiving element LRD3 to constitute a third light-sensing pixel PSR3. That is, the first sensor circuit S21 and the third light-receiving element LRD3 may constitute the third light-sensing pixel PSR3. The second sensor circuit SC22 of the second pixel row R2 may be electrically connected to the fourth light-receiving element LRD4 to constitute a fourth light-sensing pixel PSR4. That is, the second sensor circuit SC22 and the fourth light-receiving element LRD4 may constitute the fourth light-sensing pixel PSR4. However, the disclosure is not limited thereto. In some embodiments, only some of the sensor circuits SC11 to SC44 may be provided, and be connected to a plurality of light-receiving elements.

The first sensor circuit SC11 of the first pixel row R1 may be disposed between the first sub-pixel unit SPU1 and the second sub-pixel unit SPU2, which are included in the pixel unit PU. In an embodiment, the first and second pixel circuits PXC11 and PXC12 of the first sub-pixel R1 may be included in the first sub-pixel unit SPU1, and the third and fourth pixel circuits PXC13 and PXC14 of the first pixel row R1 may be included in the second sub-pixel unit SPU2, for example. Therefore, at least two pixel circuits (e.g., PXC13 and PXC14) may be disposed between the first sensor circuit SC11 and the second sensor circuit SC12, which are adjacent to each other on the first pixel row R1. However, the disclosure is not limited thereto. In some embodiments, as shown in FIG. 4, the first sensor circuit SC11 of the first pixel row R1 may be disposed between the first pixel circuit PXC11 and the second pixel circuit PXC12, and the second sensor circuit SC12 of the first pixel row R1 may be disposed between the fifth pixel circuit PXC15 and the sixth pixel circuit PXC16.

Similarly to the first sensor circuit SC11 of the first pixel row R1, the second sensor circuit SC12 of the first pixel row R1, the first sensor circuit SC21 of the second pixel row R2, and the second sensor circuit SC22 of the second pixel row R2 may be disposed between the first sub-pixel unit SPU1 and the second sub-pixel unit SPU2. However, the arrangement of the sensor circuits SC11 to SC44 is not limited thereto. In some embodiments, as shown in FIG. 4, four pixel circuits, e.g., the second pixel circuit PXC12, the third pixel circuit PXC13, the fourth pixel circuit PXC14, and the fifth pixel circuit PXC15 may be disposed between the first sensor circuit SC11 and the second sensor circuit SC12, which are adjacent to each other, on the first pixel row R1. Four pixel circuits, e.g., the second pixel circuit PXC22, the third pixel circuit PXC23, the fourth pixel circuit PXC24, and the fifth pixel circuit PXC25 may be disposed between the first sensor circuit SC21 and the second sensor circuit SC22, which are adjacent to each other, on the second pixel row R2. Four pixel circuits, e.g., the second pixel circuit PXC32, the third pixel circuit PXC33, the fourth pixel circuit PXC34, and the fifth pixel circuit PXC35 may be disposed between the first sensor circuit SC31 and the second sensor circuit SC32, which are adjacent to each other, on the third pixel row R3. Four pixel circuits, e.g., the second pixel circuit PXC42, the third pixel circuit PXC43, the fourth pixel circuit PXC44, and the fifth pixel circuit PXC45 may be disposed between the first sensor circuit SC41 and the second sensor circuit SC42, which are adjacent to each other, on the fourth pixel row R4.

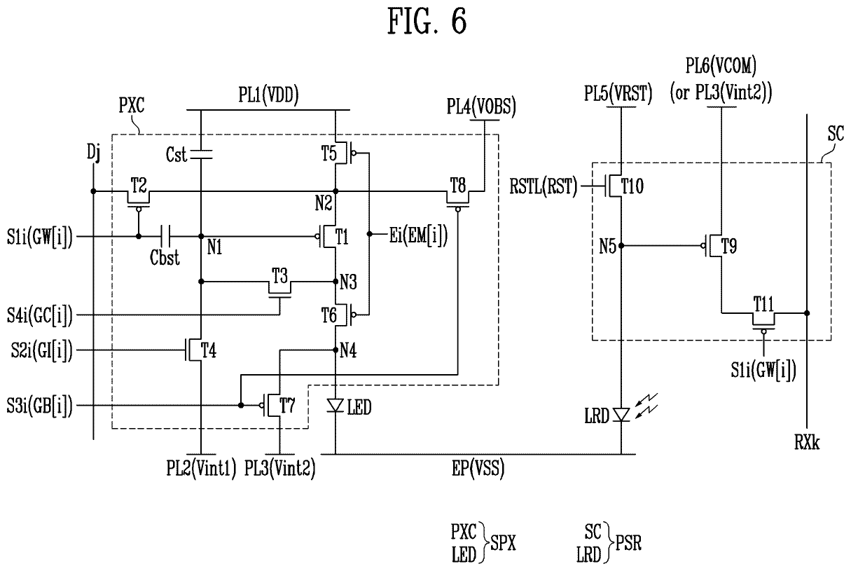

FIG. 6 is a schematic circuit diagram illustrating an embodiment of the sub-pixel SPX and the light-sensing pixel PSR, which are included in the display area shown in FIG. 1. In FIG. 6, for convenience of description, a sub-pixel SPX which is disposed on an ith horizontal line (or ith pixel row) and is connected to a jth data line Dj will be illustrated.

Referring to FIGS. 1 and 6, a sub-pixel SPX and a light-sensing pixel PSR may be disposed on an ith horizontal line.

The sub-pixel SPX may include a light-emitting element LED and a pixel circuit PXC. In embodiments, the pixel circuit PXC may include first, second, third, fourth, fifth, sixth, seventh, and eighth transistors T1, T2, T3, T4, T5, T6, T7, and T8, a storage capacitor Cst, and a boost capacitor Cbst.

The first transistor T1 (or driving transistor) may be electrically connected between a first power line PL1 and a first electrode (or anode electrode) of the light-emitting element LED. The first transistor T1 may include a gate electrode electrically connected to a first node N1. The first transistor T1 may control an amount of current (or driving current) flowing from the first power line PL1 to an electrode EP (or power line) via the light-emitting element LED, based on a voltage of the first node N1. A first power voltage VDD may be supplied to the first power line PL1, and a second power voltage VSS may be supplied to the electrode EP. The first power voltage VDD may be set as a voltage higher than the second power voltage VSS.

The second transistor T2 may be electrically connected between a jth data line Dj and a second node N2. A gate electrode of the second transistor T2 may be connected to a 1ith scan line S1i (or first scan line). The second transistor T2 may be turned on when a first scan signal GW[i] (e.g., the first scan signal GW[i] having a relatively low level) is supplied to the 1ith scan line S1i, to electrically connect the jth data line Dj and the second node N2 to each other. When each of the first transistor T1 and the third transistor T3 is in a turn-on state, the second transistor T2 may transfer a data signal of the jth data line Dj to the second node N2 in response to the first scan signal GW[i].

The third transistor T3 may be electrically connected between the first node N1 and a third node N3. A gate electrode of the third transistor T3 may be electrically connected to a 4ith scan line S4i (or third scan line). The third transistor T3 may be turned on when a fourth scan signal GC[i] is supplied to the 4ith scan line S4i.

The fourth transistor T4 may be electrically connected between the first node N1 and a second power line PL2. A gate electrode of the fourth transistor T4 may be electrically connected to a 2ith scan line S2i (or second scan line). A first initialization power voltage Vint1 may be supplied to the second power line Pl2. The second power line PL2 may be also referred to as a first initialization power line. The fourth transistor T4 may be turned on by a second scan signal GI[i] supplied to the 2ith scan line S2i. When the fourth transistor T4 is turned on, the first initialization power voltage Vint1 may be supplied to the first node N1 (i.e., the gate electrode of the first transistor T1).

The fifth transistor T5 may be electrically connected between the first power line PL1 and the second node N2. A gate electrode of the fifth transistor T5 may be electrically connected to an ith emission control line Ei. The sixth transistor T6 may be electrically connected between the third node N3 and the light-emitting element LED (or a fourth node N4). A gate electrode of the sixth transistor T6 may be electrically connected to the ith emission control line Ei. The fifth transistor T5 and the sixth transistor T6 may be turned off when an emission control signal EM[i] (e.g., the emission control signal EM[i] having a relatively high level) is supplied to the ith emission control line Ei, and be turned on in other cases.

The seventh transistor T7 may be electrically connected between the first electrode of the light-emitting element LED (i.e., the fourth node N4) and a third power line PL3. A gate electrode of the seventh transistor T7 may be electrically connected to a 3ith scan line S3i. A second initialization power voltage Vint2 may be supplied to the third power line PL3. The third power line PL3 may be also referred to as a second initialization power line. In some embodiments, the second initialization power voltage Vint2 may be equal to or different from the first initialization power voltage Vint1. The seventh transistor T7 may be turned on by a third scan signal GB[i] supplied to the 3ith scan line S3i, to supply the second initialization power voltage Vint2 to the first electrode of the light-emitting element LED.

The eighth transistor T8 may be electrically connected between the second node N2 and a fourth power line PL4. A gate electrode of the eighth transistor T8 may be electrically connected to the 3ith scan line S3i. A bias voltage VOBS may be supplied to the fourth power line PL4. The eighth transistor T8 may be turned on by the third scan signal GB[i] supplied to the 3ith scan line S3i, to supply the bias voltage VOBS to the second node N2.

The storage capacitor Cst may be connected or formed between the first power line PL1 and the first node N1.

The boost capacitor Cbst (or capacitor) may be connected or formed between the gate electrode of the second transistor T2 and the gate electrode of the first transistor T1.

The light-sensing pixel PSR may include a sensor circuit SC and a light-receiving element LRD. The sensor circuit SC may include ninth, tenth, and eleventh transistors T9, T10, and T11.

The ninth and eleventh transistors T9 and T11 may be connected in series between a sixth power line PL6 and a kth readout line RXk (k is a natural number equal to or less than o).

The ninth transistor T9 (or first sensor transistor) may be electrically connected between the sixth power line PL6 and the eleventh transistor T11. A gate electrode of the ninth transistor T9 may be electrically connected to a fifth node N5 (or sensor node). The ninth transistor T9 may control a current flowing from the sixth power line PL6 to the kth readout line RXk through the eleventh transistor T11 in response to a voltage of the fifth node N5. A common voltage VCOM may be supplied to the sixth power line PL6.

In accordance with embodiments, the sixth power line PL6 may be electrically connected to the third power line PL3 or be unitary with the third power line PL3, and the common voltage VCOM applied to the sixth power line PL6 may be equal to the second initialization power voltage Vint2. However, the disclosure is not limited thereto. In another embodiment, the sixth power line PL6 may be electrically connected to the second power line PL2 or be unitary with the second power line PL2, and the common voltage VCOM applied to the sixth power line PL6 may be equal to the first initialization power voltage Vint1.

The eleventh transistor T11 (“second sensor transistor” or “switching transistor”) may be electrically connected between the ninth transistor T9 and the kth readout line RXk. A gate electrode of the eleventh transistor T11 may be connected to the 1ith scan line S1i. That is, the gate electrode of the eleventh transistor T11 and the gate electrode of the second transistor T2 may share the 1ith scan line S1i.

The tenth transistor T10 (or third sensor transistor) may be electrically connected between a fifth power line PL5 (or reference power line) and the fifth node N5. A gate electrode of the tenth transistor T10 may be electrically connected to a reset line RSTL. A reset voltage VRST may be supplied to the fifth power line PL5. The reset voltage VRST may be a direct-current (“DC”) voltage having a constant level. In an embodiment, the reset voltage VRST may be about −7 volts (V), for example, but the disclosure is not limited thereto.

At least one light-receiving element LRD may be electrically connected between the fifth node N5 and the electrode EP to which the second power voltage VSS is applied.

The light-receiving element LRD may generate a charge (or current), based on incident light. That is, the light-receiving element LRD may perform a function of photoelectric conversion. In an embodiment, the light-receiving element LRD may be implemented as a photo diode, for example.

When the tenth transistor T10 is turned on by a reset signal RST supplied to the reset line RSTL, the reset voltage VRST may be supplied to the fifth node N5. In an embodiment, the voltage of the fifth node N5 may be reset by the reset voltage VRST, for example. The light-receiving element LRD may perform the function of photoelectric conversion from after the reset voltage VRST is applied to the fifth node N5.

The voltage of the fifth node N5 may be changed by an operation of the light-receiving element LRD. The voltage of the fifth node (or the charge or current generated by the light-receiving element LRD) may be changed according to an intensity of light incident into the light-receiving element LRD and a time for which the light is incident (or a time for which the light-receiving element LRD is exposed to the light).

When the eleventh transistor T11 is turned on by the first scan signal GW[i] supplied to the 1ith scan line S1i, a detection value (current and/or voltage) generated based on the voltage of the fifth node N5 may flow in the kth readout line RXk.

Each of the pixel circuit PXC and the sensor circuit SC may include a P-type transistor and an N-type transistor. The third transistor T3, the fourth transistor T4, and the tenth transistor T10 may be formed with an oxide semiconductor transistor including an oxide semiconductor (or second type semiconductor). In an embodiment, the third transistor T3, the fourth transistor T4, and the tenth transistor T10 may be formed with an N-type oxide semiconductor transistor, and include an oxide semiconductor layer as an active layer, for example. However, the disclosure is not limited thereto. The other transistors (e.g., the first, second, fifth, sixth, seventh, eighth, ninth, and eleventh transistors T1, T2, T5, T6, T7, T8, T9, and T11) may be formed with a poly-silicon transistor including a silicon semiconductor (or first type semiconductor), and include a poly-silicon semiconductor layer as an active layer. In an embodiment, the active layer may be formed through a low-temperature poly-silicon (“LTPS”) process, for example.

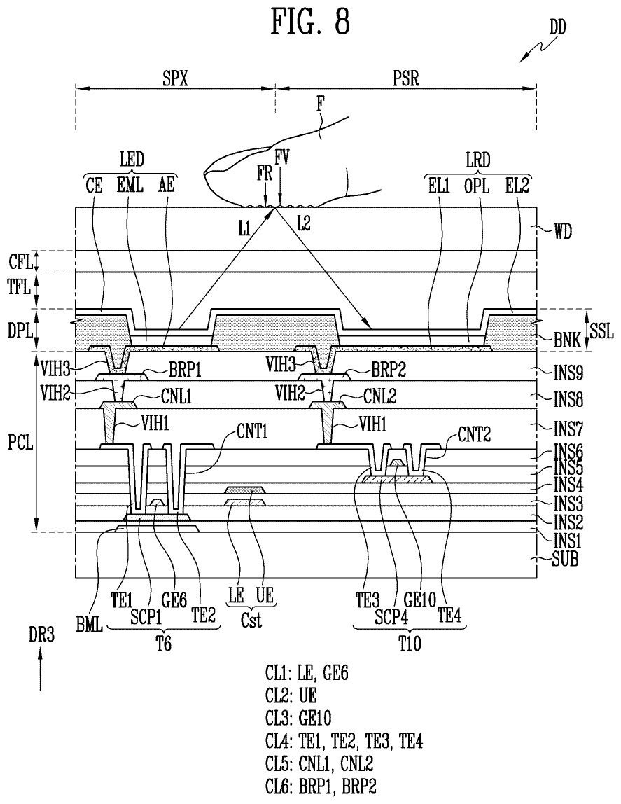

Hereinafter, a stacked structure (or cross-sectional structure) of a sub-pixel SPX including a light-emitting element LED and a light-sensing pixel PSR including a light-receiving element LRD will be mainly described with reference to FIGS. 7 and 8.

FIG. 7 is a schematic cross-sectional view illustrating an embodiment of one area of a display device DD in accordance with the disclosure. FIG. 8 is a schematic cross-sectional view illustrating a reflection path of light in the display device DD shown in FIG. 7.

In FIGS. 7 and 8, a section of a portion corresponding to the sixth transistor T6 among the first to eighth transistors T1 to T8 shown in FIG. 6 and a section of a portion corresponding to the tenth transistor T10 among the ninth to eleventh transistors T9 to T11 shown in FIG. 6 are illustrated.

Referring to FIGS. 1 to 8, the display device DD may include a sub-pixel SPX and a light-sensing pixel PSR, which are provided in one area of a substrate SUB.

A pixel circuit layer PCL of the sub-pixel SPX and the light-sensing pixel PSR may be disposed on the substrate SUB. At least one insulating layer may be disposed in the pixel circuit layer PCL. The insulating layer may include a first insulating layer INS1, a second insulating layer INS2, a third insulating layer INS3, a fourth insulating layer INS4, a fifth insulating layer INS5, a sixth insulating layer INS6, a seventh insulating layer INS7, an eighth insulating layer INS8, and a ninth insulating layer INS9, which are sequentially stacked along a third direction DR3 on the substrate SUB.

The first insulating layer INS1 (or buffer layer) may be disposed on the substrate SUB. The first insulating layer INS1 may prevent an impurity from being diffused into a sixth transistor T6 and a tenth transistor T10. The first insulating layer INS1 may be an inorganic layer including an inorganic material (or substance). The first insulating layer INS1 may include at least one of silicon nitride (SiNₓ), silicon oxide (SiOₓ), silicon oxynitride (SiOₓN_{y}), and aluminum oxide (AlOₓ). The first insulating layer INS1 may be provided as a single layer, but be provided as a multi-layer including at least two layers. The first insulating layer INS1 may be omitted according to a material of the substrate SUB, a process condition, or the like.

The second insulating layer INS2 (or first gate insulating layer) may be disposed on the first insulating layer INS1. The second insulating layer INS2 may include the same material as that of the first insulating layer INS1 or include a material appropriate (or selected) from the materials exemplified as the material constituting the first insulating layer INS1. In an embodiment, the second insulating layer INS2 may be an inorganic insulting layer including an inorganic material, for example.

The third insulating layer INS3 (or second gate insulating layer) may be disposed on the second insulating layer INS2. The third insulating layer INS3 may include the same material as that of the first insulating layer INS1 or include a material appropriate (or selected) from the materials exemplified as the material constituting the first insulating layer INS1.

The fourth insulating layer INS4 (or first inter-insulating layer) may be disposed on the third insulating layer INS3. The fourth insulating layer INS4 may be an inorganic layer including an inorganic material or an organic layer including an organic material.

The fifth insulating layer INS5 (or third gate insulating layer) may be disposed on the fourth insulating layer INS4. The fifth insulating layer INS5 may be an inorganic layer including an inorganic material or an organic layer including an organic material.

The sixth insulating layer INS6 (or second inter-insulating layer) may be disposed on the fifth insulating layer INS5. The sixth insulating layer INS6 may be an inorganic layer including an inorganic material or an organic layer including an organic material.

The seventh insulating layer INS7 (or first via layer) may be disposed on the sixth insulating layer INS6. The seventh insulating layer INS7 may be an inorganic layer including an inorganic material or an organic layer including an organic material.

The inorganic layer may include, e.g., at least one of silicon nitride (SiNₓ), silicon oxide (SiOₓ), silicon oxynitride (SiOₓN_{y}), and aluminum oxide (AlOₓ). The organic layer may include, e.g., at least one of acrylic resin, epoxy resin, phenolic resin, polyamide resin, polyimide resin, unsaturated polyester resin, poly-phenylene ether resin, poly-phenylene sulfide resin, and benzocyclobutene resin. In embodiments, the seventh insulating layer INS7 may be an organic layer.

The eighth insulating layer INS8 (or second via layer) may be disposed on the seventh insulating layer INS7. The eighth insulating layer INS8 may include the same material as that of the seventh insulating layer INS7 or include a material appropriate (or selected) from the materials exemplified as the material constituting the seventh insulating layer INS7. In an embodiment, the eighth insulating layer INS8 may be an organic layer including an organic material, for example.

The ninth insulating layer INS9 (or third via layer) may be disposed on the eighth insulating layer INS8. The ninth insulating layer INS9 may include the same material as that of the seventh insulating layer INS7 or include a material appropriate (or selected) from the materials exemplified as the material constituting the seventh insulating layer INS7. In an embodiment, the ninth insulating layer INS9 may be an organic layer including an organic material, for example.

The pixel circuit layer PCL may include one or more conductive layers disposed between the above-described insulating layers. In an embodiment, the conductive layers may include a first conductive layer CL1 disposed between the second insulating layer INS2 and the third insulating layer INS3, a second conductive layer CL2 disposed between the third insulating layer INS3 and the fourth insulating layer INS4, a third conductive layer CL3 disposed between the fifth insulating layer INS5 and the sixth insulating layer INS6, a fourth conductive layer CL4 disposed between the sixth insulating layer INS6 and the seventh insulating layer INS7, a fifth conductive layer CL5 disposed between the seventh insulating layer INS7 and the eighth insulating layer INS8, and a sixth conductive layer CL6 disposed between the eighth insulating layer INS8 and the ninth insulating layer INS9, for example. The insulating layers and the conductive layers are not limited to the above-described embodiment. In some embodiments, another insulating layer and another conductive layer in addition to the insulating layer and the conductive layers may be disposed in the pixel circuit layer PCL.

In embodiments, a first semiconductor layer may be disposed between the first insulating layer INS1 and the second insulating layer INS2. The first semiconductor layer may include a silicon semiconductor. In an embodiment, the silicon semiconductor may include amorphous silicon, polycrystalline silicon, or the like, for example. The first semiconductor layer may include low temperature poly-silicon, but the disclosure is not limited thereto. The first semiconductor layer may include a first semiconductor region having a relatively high conductivity and a second semiconductor region having a relatively low conductivity. The first semiconductor region may be doped with an N-type dopant or a P-type dopant. A P-type transistor may include a doping region doped with a P-type dopant, and an N-type transistor may include a doping region doped with an N-type dopant. The second semiconductor region may be a non-doping region or a region doped at a relatively low concentration as compared with the first semiconductor region. A conductivity of the first semiconductor region may be higher than a conductivity of the second semiconductor region. The first semiconductor region may substantially serve an electrode or a signal line. The second semiconductor region may substantially correspond to an active pattern (or channel region) of a transistor. A portion of the first semiconductor layer may be an active pattern region of the transistor, another portion of the first semiconductor layer may be a source/drain region (or source/drain electrode) of the transistor, and another portion of the first semiconductor layer may be a connection electrode or a connection signal line. However, the disclosure is not limited thereto.

In embodiments, a second semiconductor layer may be disposed between the fourth insulating layer INS4 and the fifth insulating layer INS5. The second semiconductor layer may include an oxide semiconductor. The oxide semiconductor may include a plurality of regions divided according to whether a metal oxide has been reduced. A region in which the metal oxide is reduced (hereinafter, also referred to as a “reduction region”) may have a relatively high conductivity as compared with a region in which the metal oxide is not reduced (hereinafter, also referred to as a “non-reduction region”). The reduction region may be substantially used as a source/drain region of a transistor or a signal line. The non-reduction region may substantially correspond to an active pattern (or channel region) of the transistor. A portion of the second semiconductor layer may be an active pattern of the transistor, another portion of the second semiconductor layer may be a source/drain region (or source/drain electrode) of the transistor, and another portion of the second semiconductor layer may be a signal transfer region. However, the disclosure is not limited thereto.

The sixth transistor T6 and the tenth transistor T10 may be disposed in the pixel circuit layer PCL.

The sixth transistor T6 may include a gate electrode GE6 (hereinafter, also referred to as a “sixth gate electrode”), a first semiconductor pattern SCP1, a first terminal TE1, and a second terminal TE2. The tenth transistor T10 may include a gate electrode GE10 (hereinafter, also referred to as a “tenth gate electrode”), a fourth semiconductor pattern SCP4, a third terminal TE3, and a fourth terminal TE4.

The first semiconductor pattern SCP1 may be disposed on the first insulating layer INS1, and be configured with the first semiconductor layer. The first semiconductor pattern SCP1 may include a channel region, a first contact region connected to one end of the channel region, and a second contact region connected to an opposite end of the channel region. The second insulating layer INS2 may be disposed over the first semiconductor pattern SCP1.

The sixth gate electrode GE6 may be disposed on the second insulating layer INS2, and be configured with the first conductive layer CL1. The first conductive layer CL1 may be formed as a single layer or a multi-layer, which includes or consists of molybdenum, copper, chromium, gold, silver, titanium, nickel, neodymium, indium, tin, and/or any oxide or alloy thereof. In an embodiment, the first conductive layer CL1 may be formed as a multi-layer in which titanium, copper, and/or indium tin oxide are sequentially or repeatedly stacked, for example, but the disclosure is not limited thereto. The sixth gate electrode GE6 may overlap with one region of the first semiconductor pattern SCP1. The one region of the first semiconductor pattern SCP1, which overlaps with the sixth gate electrode GE6, may be a channel region of the sixth transistor T6. The third insulating layer INS3 may be disposed over the sixth gate electrode GE6.

The first terminal TE1 and the second terminal TE2 may be disposed on the sixth insulating layer INS6. The first terminal TE1 and the second terminal TE2 may be configured with the fourth conductive layer CL4. The fourth conductive layer CL4 may be formed as a single layer or a multi-layer, which includes or consists of molybdenum, copper, chromium, gold, silver, titanium, nickel, neodymium, indium, tin, and/or any oxide or alloy thereof.

The first terminal TE1 may be electrically connected to the second contact region of the first semiconductor pattern SCP1 through a first contact portion CNT1 penetrating the second insulating layer INS2, the third insulating layer INS3, the fourth insulating layer INS4, the fifth insulating layer INS5, and the sixth insulating layer INS6. The first terminal TE1 may be electrically connected to an anode electrode AE of a light-emitting element LED. The second terminal TE2 may be electrically connected to the first contact region of the first semiconductor pattern SCP1 through another first contact portion CNT1 penetrating the second insulating layer INS2, the third insulating layer INS3, the fourth insulating layer INS4, the fifth insulating layer INS5, and the sixth insulating layer INS6.

The seventh insulating layer INS7 may be disposed over the first terminal TE1 and the second terminal TE2.

The fourth semiconductor pattern SCP4 may be disposed on the fourth insulating layer INS4. The fourth semiconductor pattern SCP4 may be configured with the second semiconductor layer. The fourth semiconductor pattern SCP4 may include a channel region, a first contact region connected to one end of the channel region, and a second contact region connected to an opposite end of the channel region. The fifth insulating layer INS5 may be disposed over the fourth semiconductor pattern SCP4.

The tenth gate electrode GE10 may be disposed on the fifth insulating layer INS5. The tenth gate electrode GE10 may be configured with the third conductive layer CL3. The third conductive layer CL3 may include the same material as that of the first conductive layer CL1 or the fourth conductive layer CL4 or include a material appropriate (or selected) from the materials exemplified as the material constituting the first conductive layer CL1 or the fourth conductive layer CL4. The tenth gate electrode GE10 may overlap with one region of the fourth semiconductor pattern SCP4. The one region of the fourth semiconductor pattern SCP4, which overlaps with the tenth gate electrode GE10, may be a channel region of the tenth transistor T10.

The sixth insulating layer INS6 may be disposed over the tenth gate electrode GE10.

The third terminal TE3 and the fourth terminal TE4 may be disposed on the sixth insulating layer INS6. The third terminal TE3 and the fourth terminal TE4 may be configured with the fourth conductive layer CL4.

The third terminal TE3 may be electrically connected to the first contact region of the fourth semiconductor pattern SCP4 through a second contact portion CNT2 penetrating the fifth insulating layer INS5 and the sixth insulating layer INS6. The fourth terminal TE4 may be electrically connected to the second contact region of the fourth semiconductor pattern SCP4 through another second contact portion CNT2 penetrating the fifth insulating layer INS5 and the sixth insulating layer INS6. The third terminal TE3 and the fourth terminal TE4 may be disposed on the sixth insulating layer INS6 to be spaced apart from each other. The seventh insulating layer INS7 may be disposed over the third terminal TE3 and the fourth terminal TE4.

In some embodiments, the pixel circuit layer PCL may further include a bottom metal pattern BML disposed on the substrate SUB. The bottom metal pattern BML may overlap with the sixth transistor T6. In some embodiments, the bottom metal pattern BML may be electrically connected to the sixth transistor T6, to stabilize the channel region of the sixth transistor T6.

A storage capacitor Cst may be disposed in the pixel circuit layer PCL. The storage capacitor Cst may include a lower electrode LE and an upper electrode UE.

The lower electrode LE may be disposed on the second insulating layer INS2. The lower electrode LE may be configured with the first conductive layer CL1, and be provided in the same layer as the sixth gate electrode GE6. However, the disclosure is not limited thereto. The third insulating layer INS3 may be disposed over the lower electrode LE.

The upper electrode UE may be disposed on the third insulating layer INS3. The upper electrode UE may be configured with the second conductive layer CL2, but the disclosure is not limited thereto. The second conductive layer CL2 may include the same material as that of the first conductive layer CL1 or the fourth conductive layer CL4 or include a material appropriate (or selected) from the materials exemplified as the material constituting the first conductive layer CL1 or the fourth conductive layer CL4. The upper electrode UE may overlap with the lower electrode LE with the third insulating layer INS3 interposed therebetween, thereby forming a capacitance.

A first connection line CNL1, a second connection line CNL2, a first bridge pattern BRP1, and a second bridge pattern BRP2 may be disposed in the pixel circuit layer PCL.

The first connection line CNL1 and the second connection line CNL2 may be disposed on the seventh insulating layer INS7. The first connection line CNL1 and the second connection line CNL2 may be configured with the fifth conductive layer CL5. The fifth conductive layer CL5 may include the same material as that of the first conductive layer CL1 or the fourth conductive layer CL4 or include a material appropriate (or selected) from the materials exemplified as the material constituting the first conductive layer CL1 or the fourth conductive layer CL4. The first connection line CNL1 may be electrically connected to the first terminal TE1 of the sixth transistor T6 through a first via hole VIH1 penetrating the seventh insulating layer INS7. The second connection line CNL2 may be electrically connected to the third terminal of the tenth transistor T10 through another first via hole VIH1 penetrating the seventh insulating layer INS7. The eighth insulating layer INS8 may be disposed over the first connection line CNL1 and the second connection line CNL2.

The first bridge pattern BRP1 and the second bridge pattern BRP2 may be disposed on the eighth insulating layer INS8. The first bridge pattern BRP1 and the second bridge pattern BRP2 may be configured with the sixth conductive layer CL6. The sixth conductive layer CL6 may include the same material as that of the first conductive layer CL1 or the fourth conductive layer CL4 or include a material appropriate (or selected) from the materials exemplified as the material constituting the first conductive layer CL1 or the fourth conductive layer CL4. The first bridge pattern BRP1 may be electrically connected to the first connection line CNL1 through a second via hole VIH2 penetrating the eighth insulating layer INS8. The second bridge pattern BRP2 may be electrically connected to the second connection line CNL2 through another second via hole VIH2 penetrating the eighth insulating layer INS8. The ninth insulating layer INS9 may be disposed over the first and second bridge patterns BRP1 and BRP2.

A display element layer DPL may be disposed on the pixel circuit layer PCL of the sub-pixel SPX, and a sensor layer SSL may be disposed on the pixel circuit layer PCL of the light-sensing pixel PSR.

The light-emitting element LED and a bank BNK may be disposed in the display element layer DPL. The light-emitting element LED may include the anode electrode AE (or pixel electrode), a light-emitting layer EML, and a cathode electrode CE (or common electrode). The light-emitting element LED may be electrically connected to the sixth transistor T6 through the first bridge pattern BRP1 and the first connection line CNL1. The light-emitting layer EML may include a hole transport layer, an organic material layer (or light generation layer), and electron transport layer, or the like.

A light-receiving element LRD and the bank BNK may be disposed in the sensor layer SSL. The light-receiving element LRD may be an optical type fingerprint sensor. The light-receiving element LRD may sense lights reflected by ridges FR of a finger F of a user and valleys FV between the ridges FR, thereby recognizing a fingerprint of the user. In an embodiment, when the finger F of the user contacts a window WD on the window WD, first light L1 output from the light-emitting element LED (or the light-emitting layer EML) may be reflected by the ridge FR or the valley FV of the finger F, and reflected second light L2 may reach the light-receiving element LRD (or a light-receiving layer OPL) of the sensor layer SSL. The light-receiving element LRD may distinguish second light L2 reflected by the ridge FR of the finger F from second light L2 reflected by the valley of the finger F, thereby recognizing a pattern of the fingerprint of the user. The light-receiving element LRD may be electrically connected to the tenth transistor T10. The light-receiving element LRD may include a first electrode EL1 (or first sensor electrode), the light-receiving layer OPL (or photoelectric conversion layer), and a second electrode EL2 (or second sensor electrode).

The anode electrode AE and the first electrode EL1 may be disposed on the ninth insulating layer INS9. The anode electrode AE and the first electrode EL1 may include or consist of a metal layer such as silver, magnesium, aluminum, platinum, palladium, gold, nickel, neodymium, iridium, chromium, or any alloy thereof, and/or indium tin oxide (“ITO”), indium zinc oxide (“IZO”), zinc oxide (ZnO), indium tin zinc oxide (“ITZO”), or the like. However, the disclosure is not limited thereto. The anode electrode AE may be electrically connected to the first bridge pattern BRP1 through a third via hole VIH3 penetrating the ninth insulating layer INS9. The first electrode EL1 may be electrically connected to the second bridge pattern BRP2 through another third via hole VIH3 penetrating the ninth insulating layer INS9.

The anode electrode AE and the first electrode EL1 may be simultaneously or sequentially formed through patterning using a mask.

The bank BNK may be a pixel defining layer defining (or partitioning) an emission area EMA of the sub-pixel SPX and a light-receiving area FXA of the light-sensing pixel PSR. The bank BNK may be an organic layer including an organic material (or substance). The organic material may include acrylic resin, epoxy resin, phenolic resin, polyamide resin, polyimide resin, or the like. The bank BNK may be disposed on the ninth insulating layer INS9 in a non-emission area NEA of the sub-pixel SPX and the light-sensing pixel PSR.

In some embodiments, the bank BNK may include a light absorption material or have a light absorber coated thereon, to absorb light introduced from the outside. In an embodiment, the bank BNK may include a carbon-based black pigment, for example, but the disclosure is not limited thereto. The bank BNK may include an opaque metal material, such as chromium, molybdenum, any alloy of molybdenum and titanium, tungsten, vanadium, niobium, tantalum, manganese, cobalt or nickel, which has a relatively high absorption rate. The bank BNK may define openings corresponding to the emission area EMA and the light-receiving area FXA.

The light-emitting layer EML may be disposed on the anode electrode AE. The light-emitting layer EML may include an organic light-emitting layer. The light-emitting layer EML may emit light such as red light, green light or blue light according to an organic material included in the light-emitting layer EML.

The light-receiving layer OPL may be disposed on the first electrode EL1. The light-receiving layer OPL may release electrons, corresponding to light in a predetermined wavelength bank, thereby sensing an intensity of the light.

The light-receiving layer OPL may include a relatively low molecular organic material (or substance). In an embodiment, the light-receiving layer OPL may include or consist of a phthalocyanine compound including at least one metal selected from the group including copper (Cu), iron (Fe), nickel (Ni), cobalt (Co), manganese (Mn), aluminum (Al), palladium (Pd), tin (Sn), indium (In), lead (Pb), titanium (Ti), rubidium (Rb), vanadium (V), gallium (Ga), terbium (Tb), cerium (Ce), lanthanum (La), and zinc (Zn), for example.

In an alternative embodiment, the relatively low molecular organic material included in the light-receiving layer OPL may be formed as a bi-layer including a layer including a phthalocyanine compound including at least one metal selected from the group including copper (Cu), iron (Fe), nickel (Ni), cobalt (Co), manganese (Mn), aluminum (Al), palladium (Pd), tin (Sn), indium (In), lead (Pb), titanium (Ti), rubidium (Rb), vanadium (V), gallium (Ga), terbium (Tb), cerium (Ce), lanthanum (La), and zinc (Zn) and a layer including C60, or be formed as a mixing layer in which the phthalocyanine compound and the C60 are mixed. However, the disclosure is not limited to the above-described embodiment. In some embodiments, the light-receiving layer OPL may include a relatively high molecular organic layer.

The cathode electrode CE may be disposed on the light-emitting layer EML, and the second electrode EL2 may be disposed on the light-receiving layer OPL. The cathode electrode CE and the second electrode EL2 may correspond to a common electrode unitary in the display area DA. The second power voltage VSS may be supplied to the cathode electrode CE and the second electrode EL2.

The cathode electrode CE and the second electrode EL2 may include or consist of a metal layer such as Ag, Mg, Al, Pt, Pd, Au, Ni, Nd, Ir or Cr, and/or a transparent conductive layer such as ITO, IZO, ZnO or ITZO. In embodiments, the cathode electrode CE and the second electrode EL2 may be formed as a multi-layer including at least two layers including a metal thin film layer. In an embodiment, the cathode electrode CE and the second electrode EL2 may be formed a triple layer of ITO/Ag/ITO, for example.

A thin film encapsulation layer TFL may be entirely formed over the cathode electrode CE and the second electrode EL2.

The thin film encapsulation layer TFL may be formed as a single layer, but be formed as a multi-layer. The thin film encapsulation layer TFL may include a plurality of insulating layers covering the light-emitting element LED and the light-receiving element LRD. Specifically, the thin film encapsulation layer TFL may include at least one inorganic layer and at least one organic layer. In an embodiment, the thin film encapsulation layer TFL may have a structure in which an inorganic layer and an organic layer are alternately stacked, for example.

A color filter layer CFL may be disposed on the thin film encapsulation layer TFL. The color filter layer CFL may include a light-blocking pattern and a color filter. The light-blocking pattern may be disposed on the thin film encapsulation layer TFL to correspond to the non-emission area NEA surrounding the emission area EMA of the sub-pixel SPX and the light-receiving area FXA of the light-sensing pixel PSR, and the color filter may be disposed on the thin film encapsulation layer TFL to correspond to the emission area EMA and the light-receiving area FXA. The above-described color filter layer CFL may be used as an anti-reflection layer which blocks external light reflection.

The window WD may be disposed on the color filter layer CFL.

The window WD may protect an exposed surface of the display device DD (or the display panel (refer to “100” shown in FIG. 1)). The window WD may protect the display device DD from external impact, and provide an input surface and/or a display surface to the user. The window WD (or cover glass) may have a multi-layer structure selected from an organic substrate, plastic, a film, and a plastic substrate. The multi-layer structure may be formed through a continuous process or an adhesion process using an adhesive layer. The whole or a portion of the window WD may have flexibility.

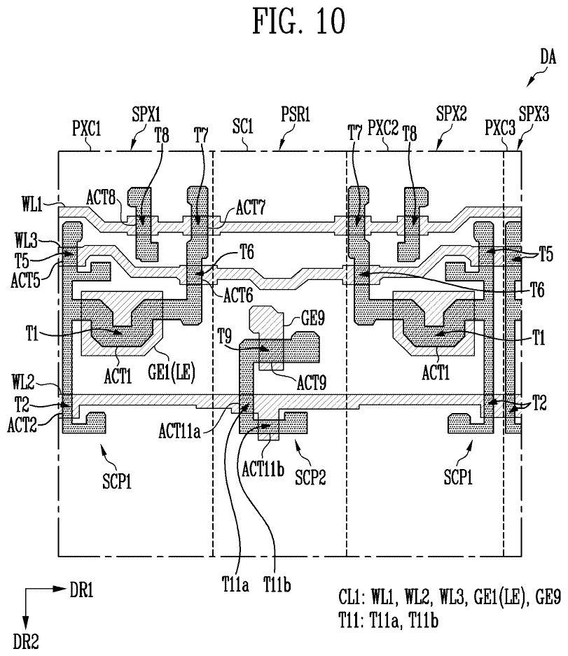

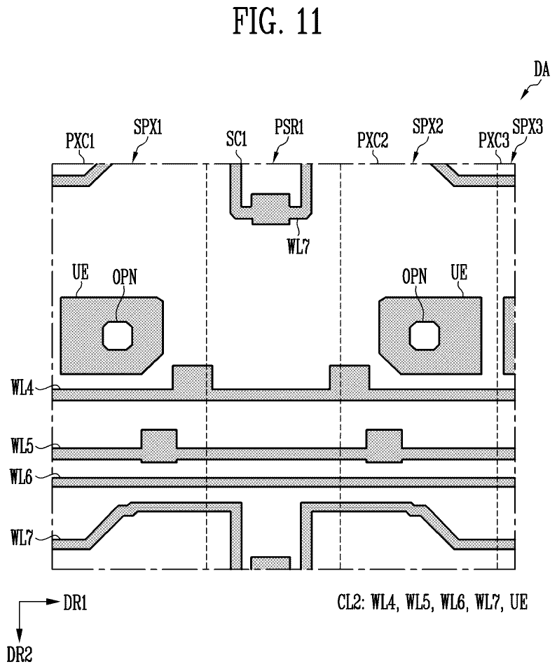

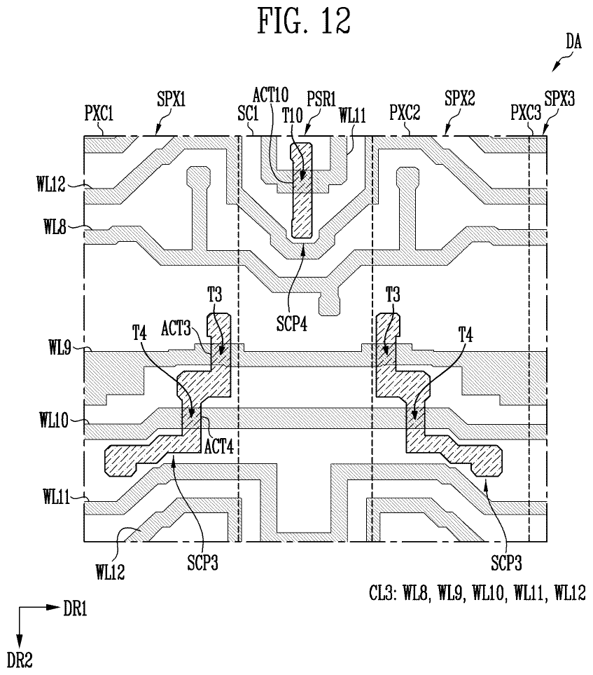

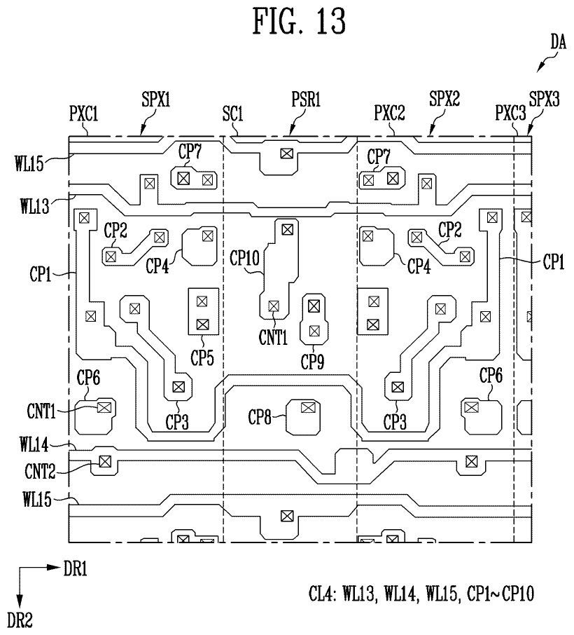

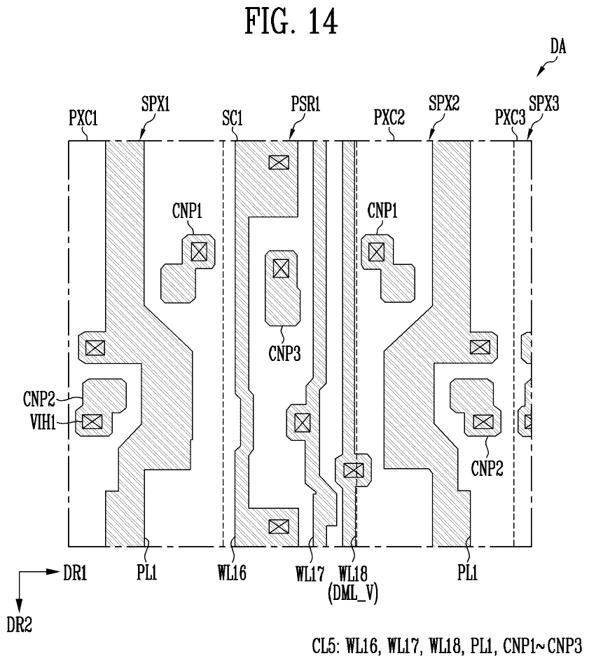

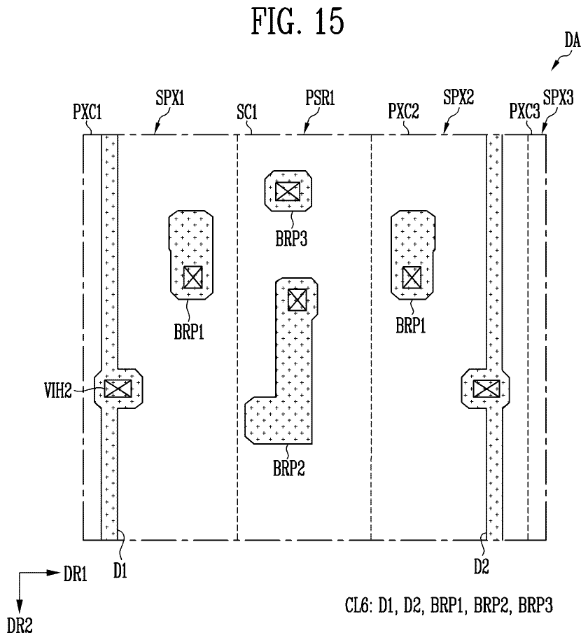

FIG. 9 is a schematic plan view illustrating an embodiment of sub-pixels SPX1 to SPX3 and a first light-sensing pixel PSR1 in accordance with the disclosure. FIG. 10 is a schematic plan view illustrating only first, second, fifth, sixth, seventh, eighth, ninth, and eleventh transistors T1, T2, T5, T6, T7, T8, T9, and T11 and components included in a first conductive layer CL1 in FIG. 9. FIG. 11 is a schematic plan view illustrating only components included in a second conductive layer CL2 in FIG. 9. FIG. 12 is a schematic plan view illustrating only third, fourth, and tenth transistors T3, T4, and T10 and components included in a third conductive layer CL3 in FIG. 9. FIG. 13 is a schematic plan view illustrating only component included in a fourth conductive layer CL4 in FIG. 9. FIG. 14 is a schematic plan view illustrating only component included in a fifth conductive layer CL5 in FIG. 9. FIG. 15 is a schematic plan view illustrating only component included in a sixth conductive layer CL6 in FIG. 9. FIG. 16 is a schematic plan view illustrating only components included in the fourth conductive layer, the fifth conductive layer, and the sixth conductive layer in FIG. 9. FIG. 17 is a schematic cross-sectional view taken along line I-I′ shown in FIG. 16.

In FIGS. 9 to 17, for convenience of description, a first sub-pixel SPX1, a second sub-pixel SPX2, a third sub-pixel SPX3, and a first light-sensing pixel PSR1, which are arranged on the same pixel row (or the same horizontal line).

Referring to FIGS. 1 to 17, a first sub-pixel SPX1, a second sub-pixel SPX2, and a third sub-pixel SPX3 may be arranged along the first direction DR1 in a display area DA. A first light-sensing pixel PSR1 may be disposed between the first sub-pixel SPX1 and the second sub-pixel SPX2. In an embodiment, the first sub-pixel SPX1, the first light-sensing pixel PSR1, the second sub-pixel SPX2, and the third sub-pixel SPX3 may be arranged in the display area DA (or the first pixel row (refer to “R1” shown in FIG. 4) of a substrate SUB), for example.

Each of the first to third sub-pixels SPX1 to SPX3 may include a pixel circuit PXC. In an embodiment, the first sub-pixel SPX1 may include a first pixel circuit PXC1, the second sub-pixel SPX2 may include a second pixel circuit PXC2, and the third sub-pixel SPX3 may include a third pixel circuit PXC3, for example. The first light-sensing pixel PSR1 may include a first sensor circuit SC1. The first pixel circuit PXC1 may correspond to the eleventh pixel circuit PXC11 shown in FIG. 4, the second pixel circuit PXC2 may correspond to the twelfth pixel circuit PXC12 shown in FIG. 4, the third pixel circuit PXC3 may correspond to the thirteenth pixel circuit PXC13 shown in FIG. 4, and the first sensor circuit SC1 may correspond to the eleventh sensor circuit SC11 shown in FIG. 4. The first pixel circuit PXC1 and the second pixel circuit PXC2, which have the first sensor circuit SC1 interposed therebetween, may be mirror-symmetrical to each other, and be substantially the same. For convenience, the first pixel circuit PXC1, the first sensor circuit SC1, and the second pixel circuit PXC2 will be mainly illustrated in FIGS. 9 to 17.

The first to third sub-pixels SPX1 to SPX3 may include the substrate SUB (refer to FIGS. 7 and 8), a pixel circuit layer PCL (refer to FIGS. 7 and 8), a display element layer DPL (refer to FIGS. 7 and 8), a thin film encapsulation layer TFL (refer to FIGS. 7 and 8), a color filter layer CFL (refer to FIGS. 7 and 8), and a window WD (refer to FIGS. 7 and 8). The first light-sensing pixel PSR1 may include the substrate SUB, the pixel circuit layer PCL, a sensor layer SSL (refer to FIGS. 7 and 8), the thin film encapsulation layer TFL, the color filter layer CFL, and the window WD.

The substrate SUB may include a transparent insulating material to allow light to be transmitted therethrough. The substrate SUB may be a rigid substrate or a flexible substrate.

The first to third pixel circuits PXC1 to PXC3, the first sensor circuit SC1, and signal lines may be disposed in the pixel circuit layer PCL.

A light-emitting element (refer to “LED” shown in FIG. 7) electrically connected to each of the first to third pixel circuits PXC1 to PXC3 may be disposed in the display element layer DPL. A light-receiving element (refer to “LRD” shown in FIG. 7) electrically connected to the first sensor circuit SC1 may be disposed in the sensor layer SSL.

A first insulating layer INS1, a second insulating layer INS2, a third insulating layer INS3, a fourth insulating layer INS4, a fifth insulating layer INS5, a sixth insulating layer INS6, a seventh insulating layer INS7, an eighth insulating layer INS8, and a ninth insulating layer INS9, which are sequentially stacked along the third direction DR3 from one surface of the substrate SUB.

At least one conductive layer and at least one semiconductor layer may be disposed in the pixel circuit layer PCL. In an embodiment, the pixel circuit layer PCL may include a first semiconductor layer, a first conductive layer CL1, a second conductive layer CL2, a second semiconductor layer, a third conductive layer CL3, a fourth conductive layer CL4, a fifth conductive layer CL5, and a sixth conductive layer CL6, which are sequentially stacked along the third direction DR3 from the one surface of the substrate SUB, for example.

Signal lines may be disposed in the display area DA in which the first to third sub-pixels SPX1 to SPX3 and the first light-sensing pixel PSR1 are disposed. In an embodiment, first to eighteenth lines WL1 to WL18, first and second data lines D1 and D2, and a first power line PL1 may be disposed in the display area DA, for example.

The first line WL1 may extend in the first direction DR1, and be configured with the first conductive layer CL1. The first line WL1 may be the 3ith scan line S3i described with reference to FIG. 6. One area of the first line WL1 may be a gate electrode (hereinafter, also referred to as a “seventh gate electrode”) of a seventh transistor T7 of each of the first and second pixel circuits PXC1 and PXC2. In addition, another area of the first line WL1 may be a gate electrode (hereinafter, also referred to as an “eighth gate electrode”) of an eighth transistor T8 of each of the first and second pixel circuits PXC1 and PXC2.

The second line WL2 may extend in the first direction DR1, and be spaced apart from the first line WL1. The second line WL2 may be configured with the first conductive layer CL1. The second line WL2 may be a 1ith scan line S1i described with reference to FIG. 6. One area of the second line WL2 may be a gate electrode (hereinafter, also referred to as a “second electrode”) of a second transistor T2 of each of the first and second pixel circuits PXC1 and PXC2. In addition, another area of the second line WL2 may be a gate electrode (hereinafter, also referred to as an “11ath gate electrode”) of an 11ath transistor T11a of the first sensor circuit SC1. In addition, a protrusion portion of the second line WL2 may be a gate electrode (hereinafter, also referred to as an “11bth gate electrode”) of an 11bth transistor T11b of the first sensor circuit SC1.

The third line WL3 may extend in the first direction DR1, and be spaced apart from the first and second lines WL1 and WL2. The third line WL3 may be configured with the first conductive layer CL1. In embodiments, the third line WL3 may be the ith emission control line Ei described with reference to FIG. 6. One area of the third line WL3 may be a gate electrode (hereinafter, also referred to as a fifth gate electrode”) of a fifth transistor T5 of each of the first and second pixel circuits PXC1 and PXC2. In addition, another area of the third line WL3 may be a gate electrode (hereinafter, also referred to as a “sixth gate electrode”) of a sixth transistor T6 of each of the first and second pixel circuits PXC1 and PXC2.

The fourth line WL4 may extend in the first direction DR1, and be configured with the second conductive layer CL2. The fourth line WL4 may be horizontal dummy line overlapping with the ninth line WL9 configured with the third conductive layer CL3, but the disclosure is not limited thereto.

The fifth line WL5 may extend in the first direction DR1, and be configured with the second conductive layer CL2. The fifth line WL5 may be spaced apart from the fourth line WL4. The fifth line WL5 may be a horizontal dummy line overlapping with the tenth line WL10 configured with the third conductive layer CL3.

The sixth line WL6 may extend in the first direction DR1, and be configured with the second conductive layer CL2. The sixth line WL6 may be spaced apart from the fourth and fifth lines WL4 and WL5. The sixth line WL6 may be a horizontal dummy line overlapping with the fifteenth line WL15 configured with the fourth conductive layer CL4, but the disclosure is not limited thereto. In some embodiments, a DC voltage having a constant voltage level may be applied to the sixth line WL6. In an embodiment, the sixth line WL6 may be supplied with the second power voltage VSS, for example.

The seventh line WL7 may extend in the first direction DR1, and be configured with the second conductive layer CL2. The seventh line WL7 may be spaced apart from the fourth to sixth lines WL4 to WL6. The seventh line WL7 may be a horizontal dummy line overlapping with the eleventh line WL11 configured with the third conductive layer CL3, but the disclosure is not limited thereto.

The eighth line WL8 may extend in the first direction DR1, and be configured with the third conductive layer CL3. In embodiments, the eighth line WL8 may be the third power line PL3 described with reference to FIG. 6. The eighth line WL8 may be supplied with the second initialization power voltage (refer to “Vint2” shown in FIG. 6 or the common voltage (refer to “VCOM” shown in FIG. 6)).

The ninth line WL9 may extend in the first direction DR1, and be spaced apart from the eighth line WL8. The ninth line WL9 may be configured with the third conductive layer CL3. The ninth line WL9 may be the 4ith scan line S4i described with reference to FIG. 6. One area of the ninth line WL9 may be a gate electrode (hereinafter, also referred to as a “third gate electrode”) of a third transistor T3 of each of the first and second pixel circuits PXC1 and PXC2.

The tenth line WL10 may extend in the first direction DR1, and be spaced apart from the eighth and ninth lines WL8 and WL9. The tenth line WL10 may be configured with the third conductive layer CL3. The tenth line WL10 may be the 2ith scan line S2i described with reference to FIG. 6. One area of the tenth line WL10 may be a gate electrode (hereinafter, also referred to as a “fourth gate electrode”) of a fourth transistor T4 of each of the first and second pixel circuits PXC1 and PXC2.

The eleventh line WL11 may extend in the first direction DR1, and be spaced apart from the eighth to tenth lines WL8 to WL9. The eleventh line WL11 may be configured with the third conductive layer CL3. The eleventh line WL11 may be the reset line RSTL described with reference to FIG. 6. One area of the eleventh line WL11 may be a gate electrode (hereinafter, also referred to as a “tenth gate electrode”) of a tenth transistor T10 of the first sensor circuit SC1. The tenth gate electrode may be the tenth gate electrode GE10 described with reference to FIG. 7.

The twelfth line WL12 may extend in the first direction DR1, and be spaced apart from the seventh to eleventh lines WL7 to WL11. The twelfth line WL12 may be configured with the third conductive layer CL3. The twelfth line WL12 may be the sixth power line PL6 described with reference to FIG. 6. The twelfth line WL12 may be supplied to the common voltage VCOM (or the second initialization power voltage Vint2). In embodiments, the eighth line WL8 and the twelfth line WL12 may be supplied to the same voltage, e.g., the common voltage VCOM (or the second initialization power voltage Vint2).

The thirteenth line WL13 may extend in the first direction DR1, and be configured with the fourth conductive layer CL4. The thirteenth line WL13 may be the fourth power line PL4 described with reference to FIG. 6. The thirteenth line WL13 may be supplied with the bias voltage (refer to “VOBS” shown in FIG. 6). The thirteenth line WL13 may be electrically connected to a first semiconductor pattern SCP1 of the eighth transistor T8 of each of the first and second pixel circuits PXC1 and PXC2.

The fourteenth line WL14 may extend in the first direction DR1, and be spaced apart from the thirteenth line WL13. The fourteenth line WL14 may be configured with the fourth conductive layer CL4. The fourteenth line WL14 may be the second power line PL2 (or first initialization power line) described with reference to FIG. 6. The fourteenth line WL14 may be supplied with the first initialization power voltage (refer to “Vint1” shown in FIG. 6). The fourteenth line WL14 may be electrically connected to a third semiconductor pattern SCP3 of the fourth transistor T4 of each of the first and second pixel circuits PXC1 and PXC2.

The fifteenth line WL15 may extend in the first direction DR1, and be spaced apart from the thirteenth and fourteenth lines WL13 and WL14. The fifteenth line WL15 may be configured with the fourth conductive layer CL4. The fifteenth line WL15 may be the fifth power line PL5 described with reference to FIG. 6. The fifteenth line WL15 may be supplied with the reset voltage (refer to “VRST” shown in FIG. 6). The fifteenth line WL15 may be electrically connected to a fourth semiconductor pattern SCP4 of the tenth transistor T10 of the first sensor circuit SC1.

The sixteenth line WL16 may be disposed in the first light-sensing pixel PSR1 in which the first sensor circuit SC1 is disposed, but the disclosure is not limited thereto. The sixteenth line WL16 may extend in the second direction DR2, and be configured with the fifth conductive layer CL5. The sixteenth line WL16 may be electrically connected to the fifteenth line WL15 through a first via hole VIH1 penetrating the seventh insulating layer INS7. Also, the sixteenth line WL16 may be electrically connected to a third bridge pattern BRP3 through a second via hole VIH2. The third bridge pattern BRP3 may be configured with the sixth conductive layer CL6, and be disposed in the first light-sensing pixel PSR1. The sixteenth line WL16 may be electrically connected to the third bridge pattern BRP3 disposed in a layer different from a layer in the sixteenth line WL16 is disposed through the corresponding second via hole, to be implemented in a double-layer structure. Accordingly, the line resistance of the sixteenth line WL16 may be reduced.

In embodiments, the fifteenth line WL15 may be a horizontal power line of the fifth power line PL5, and the sixteenth line WL16 may be a vertical power line of the fifth power line PL5. The fifteenth line WL15 which extends in the first direction DR1 and is configured with the fourth conductive layer CL4 and the sixteenth line WL16 which extends in the second direction DR2 and is configured with the fifth conductive layer CL5 may be electrically connected to each other, to form the fifth power line PL5 in a mesh structure. That is, the fifteenth line WL15 and the sixteenth line WL16, which are electrically connected to each other, may form the fifth power line PL5 having the mesh structure.

The seventeenth line WL17 may extend in the second direction DR2, and be configured with the fifth conductive layer CL5. The seventeenth line WL17 may be spaced apart from the sixteenth line WL16. The seventeenth line WL17 may be the kth readout line RXk (hereinafter, also referred to as a “readout line”) described with reference to FIG. 6. The seventeenth line WL17 (or readout line) may be electrically connected to an eighth conductive pattern CP8 through a first via hole VIH1 penetrating the seventh insulating layer INS7.

The eighth conductive pattern CP8 may be configured with the fourth conductive layer CL4. The eighth conductive pattern CP8 may be disposed in the first light-sensing pixel PSR1, and be electrically connected to the seventeenth line WL17 through the corresponding first via hole VIH1. Also, the eighth conductive pattern CP8 may be electrically connected to a second semiconductor pattern SCP2 of the 11bth transistor T11b through a first contact portion CNT1 penetrating the sixth insulating layer INS6, the fifth insulating layer INS5, the fourth insulating layer INS4, the third insulating layer INS3, and the second insulating layer INS2.

The eighteenth line WL18 may extend in the second direction DR2, and be spaced apart from the seventeenth line WL17 (or readout line). The eighteenth line WL18 may be configured with the fifth conductive layer. That is, the eighteenth line WL18 may be formed through the same process as the seventeenth line WL17 to include the same material, and be provided in the same layer as the seventeenth line WL17. However, the disclosure is not limited thereto. In some embodiments, the eighteenth line WL18 may be disposed in a layer different from a layer in which the seventeenth line WL17 is disposed. In an embodiment, the eighteenth line WL18 may be configured with the sixth conductive layer CL6, for example. In embodiments, the eighteenth line WL18 may be also referred to as a vertical dummy line DML_V.

In embodiments, the eighteenth line WL18 (or vertical dummy line DML_V) may be disposed between the first pixel circuit PXC1 and the second pixel circuit PXC2, and be electrically and/or physically separated from the seventeenth line WL17. The eighteenth line WL18 may be electrically connected to the fourteenth line WL14 penetrating the seventh insulating layer INS7. Accordingly, the eighteenth line WL18 may be supplied with the first initialization power voltage Vint1. The fourteenth line WL14 may be a horizontal power line of the second power line PL2, and the eighteenth line WL18 may be a vertical power line of the second power line PL2. The fourteenth line WL14 which extends in the first direction DR1 and is configured with the fourth conductive layer CL4 and the eighteenth line WL18 (or vertical dummy line DML_V) which extends in the second direction DR2 and is configured with the fifth conductive layer CL5 may be electrically connected to each other, to form the second power line PL2 in a mesh structure. That is, the fourteenth line WL14 and the eighteenth line WL18 (or vertical dummy line DML_V), which are electrically connected to each other, may form the second power line PL2 having the mesh structure. The fourteenth line WL14 may be electrically connected to the eighteenth line WL18 (or vertical dummy line DML_V) disposed in a layer different from a layer in which the fourteenth line WL14 is disposed through the corresponding first via hole VIH1, to be implemented in a double-layer structure. Accordingly, the line resistance of the fourteenth line WL14 may be reduced.

As the eighteenth line WL18 (or vertical dummy line DML_V) supplied with the first initialization power voltage Vint1 is disposed between the seventeenth line WL17 (or readout line) and the second pixel circuit PXC2, a coupling capacitance which may be generated between the seventeenth line WL17 and the second pixel circuit PXC2 may be reduced or prevented. That is, the eighteenth line WL18 (or vertical dummy line DML_V) may be used as a shielding member which reduces or prevents the coupling capacitance which may be generated between the seventeenth line WL17 and the second pixel circuit PXC2.

The first power line PL1 may extend in the second direction DR2, and be configured with the fifth conductive layer CL5. The first power line PL1 may be the first power line PL1 described with reference to FIG. 6. The first power line PL1 may be supplied with the first power voltage VDD. The first power voltage VDD may be a DC voltage having a constant voltage level. The first power line PL1 may be electrically connected to a first conductive pattern CP1 configured with the fourth conductive layer CL4 through a first via hole VIH1 penetrating the seventh insulating layer INS7.

The first conductive pattern CP1 may be configured with the fourth conductive layer CL4, to be electrically connected to the first power line PL1 through the corresponding first via hole VIH1. Also, the first conductive pattern CP1 may be electrically connected to a first semiconductor pattern SCP1 of the fifth transistor T5 of each of the first and second pixel circuits PXC1 and PXC2 through a first contact portion CNT1 penetrating the sixth insulating layer INS6, the fifth insulating layer INS5, the fourth insulating layer INS4, the third insulating layer INS3, and the second insulating layer INS2. Also, the first conductive pattern CP1 may be electrically connected to an upper electrode UE configured with the second conductive layer CL2 through a corresponding first contact portion CNT1 penetrating the sixth insulating layer INS6, the fifth insulating layer INS5, and the fourth insulating layer INS4. A first conductive pattern CP1 of the first pixel circuit PXC1 and a first conductive pattern CP1 of the second pixel circuit PXC2 may be unitary to be connected to each other, but the disclosure is not limited thereto. In some embodiments, the first conductive pattern CP1 of the first pixel circuit PXC1 and the first conductive pattern CP1 of the second pixel circuit PXC2 may be non-unitary to be electrically and physically separated from each other.

The first data line D1 may extend in the second direction DR2, and be configured with the sixth conductive layer CL6. The first data line D1 may be disposed in a layer different from a layer in which the seventeenth line WL17 as the readout line and the eighteenth line WL18 as the vertical dummy line DML_V are disposed. In an embodiment, the first data line D1 may be disposed on the seventeenth and eighteenth lines WL17 and WL18, for example. The first data line D1 may be the jth data line Dj described with reference to FIG. 6. The first data line D1 may be electrically connected to a first semiconductor pattern SCP1 of a second transistor T2 of the first pixel circuit PXC1.

The second data line D2 may extend in the second direction DR2, and be configured with the sixth conductive layer CL6. The second data line D2 may be provided in the same layer as the first data line D1, and be spaced apart from the first data line D1. The second data line D2 may be disposed in a layer different from the layer in which the seventeenth line WL17 as the readout line and the eighteenth line WL18 as the vertical dummy line DML_V are disposed. The second data line D2 may be electrically connected to a first semiconductor pattern SCP1 of a second transistor T2 of the second pixel circuit PXC2.

The first pixel circuit PXC1, the second pixel circuit PXC2, and the third pixel circuit PXC3 may have structures similar or identical to one another. In an embodiment, the first pixel circuit PXC1 disposed at the left with respect to the first sensor circuit SC1 and the second pixel circuit PXC2 disposed at the right with respect to the first sensor circuit SC1 may be mirror-symmetrical to each other, for example. Hereinafter, for convenience, the first pixel circuit PXC1 will be mainly described, and overlapping descriptions will not be repeated.

The first pixel circuit PXC1 may include first, second, third, fourth, fifth, sixth, seventh, and eighth transistors T1, T2, T3, T4, T5, T6, T7, and T8, and a storage capacitor Cst.

The first transistor T1 may include a first active pattern ACT1 and a first gate electrode GE1.

The first active pattern ACT1 may be one region of a first semiconductor pattern SCP1 overlapping with the first gate electrode GE1. The first semiconductor pattern SCP1 may be the first semiconductor layer. The first active pattern ACT1 may be a channel region of the first transistor T1.

The channel region is, e.g., a semiconductor pattern undoped with an impurity, and may be an intrinsic semiconductor. Another region of the semiconductor pattern except the channel region may be a semiconductor pattern doped with the impurity.

One region of the first semiconductor pattern SCP1, which does not overlap with the first gate electrode GE1 and is connected to one side of the first active pattern ACT1 (or the channel region) (e.g., a left side of the first active pattern ACT1 in a plan view), may be a first contact region. One region of the first semiconductor pattern SCP1, which does not overlap with the first gate electrode GE1 and is connected to an opposite side of the first active pattern ACT1 (e.g., a right side of the first active pattern ACT1 on the plan view), may be a second contact region. The first contact region and the second contact region may extend in directions opposite to each other from the first active pattern ACT1. The first contact region may be connected to the one side of the first active pattern ACT1, and be connected to a first semiconductor pattern SCP1 of the second transistor T2 and a first semiconductor pattern SCP1 of the fifth transistor T5. The second contact region may be connected to an opposite side of the first active pattern ACT1, and be connected to a first semiconductor pattern SCP1 of the sixth transistor T6.

The first gate electrode GE1 may overlap with the first active pattern ACT1, and be configured with the first conductive layer CL1. The first gate electrode GE1 may be a conductive pattern having an island shape. The first gate electrode GE1 may be electrically connected to the third transistor T3 and the fourth transistor T4 through a third conductive pattern CP3.

The third conductive pattern CP3 may be configured with the fourth conductive layer CL4. One end of the third conductive pattern CP3 may be electrically connected to the first gate electrode GE1 through a corresponding first contact portion CNT1 penetrating the sixth insulating layer INS6, the fifth insulating layer INS5, the fourth insulating layer INS4, and the third insulating layer INS3. An opposite end of the third conductive pattern CP3 may be electrically connected to one region of a third semiconductor pattern SCP3 shared by the third transistor T3 and the fourth transistor T4 through a second contact portion CNT2 penetrating the sixth insulating layer INS6 and the fifth insulating layer INS5.

The second transistor T2 may include a second active pattern ACT2 and a second gate electrode.

The second active pattern ACT2 may be one region of the first semiconductor pattern SCP1 overlapping with the second line WL2. The first semiconductor pattern SCP1 may be configured with the first semiconductor layer. The second active pattern ACT2 may be a channel region of the second transistor T2.

One region of the semiconductor pattern SCP1, which does not overlap with the second line WL2 and is connected to one side of the second active pattern ACT2 (e.g., a lower side of the second active pattern ACT2 in a plan view), may be a first contact region, and one region of the first semiconductor pattern SCP1, which does not overlap with the second line WL2 and is connected to an opposite side of the second active pattern ACT2 (e.g., an upper side of the second active pattern ACT2 on the plan view), may be a second contact region. The first contact region may be connected to the one side of the second active pattern ACT2, and be electrically connected to a sixth conductive pattern CP6. The second contact region may be connected to an opposite side of the second active pattern ACT2, and be connected to the first contact region of the first transistor T1.

The sixth conductive pattern CP6 may be configured with the fourth conductive layer CL4. The sixth conductive pattern CP6 may be electrically connected to the first semiconductor pattern SCP1 corresponding to the first contact region of the second transistor T2 through a first contact portion CNT1 penetrating the sixth insulating layer INS6, the fifth insulating layer INS5, the fourth insulating layer INS4, the third insulating layer INS3, and the second insulating layer INS2. Also, the sixth conductive pattern CP6 may be electrically connected to a second connection pattern CNP2 through a first via hole VIH1.

The second connection pattern CNP2 may be configured with the fifth conductive layer CL5, and be electrically connected to the sixth conductive pattern CP6 through a first via hole VIH1 penetrating the seventh insulating layer INS7. Also, the second connection pattern CNP2 may be electrically connected to the data line D1 configured with the sixth conductive layer CL6 through a second via hole VIH2 penetrating the eighth insulating layer INS8.

One region of the first semiconductor pattern SCP1 of the second transistor T2 may be electrically connected to the first data line D1 through the sixth conductive pattern CP6 and the second connection pattern CNP2.

The second gate electrode may be one region of the second line WL2 overlapping with the second active pattern ACT2.

The third transistor T3 may include a third active pattern ACT3 and a third gate electrode.

The third active pattern ACT3 is one region of a third semiconductor pattern SCP3 overlapping with the ninth line WL9, and may constitute a channel region of the third transistor T3. The third semiconductor pattern SCP3 may be configured with the second semiconductor layer.

One region of the third semiconductor pattern SCP3, which does not overlap with the ninth line WL9 and is connected to one side of the third active pattern ACT3 (e.g., an upper side of the third active pattern ACT3 in a plan view), may be a first contact region, and one region of the third semiconductor pattern SCP3, which does not overlap with the ninth line WL9 and is connected to an opposite side of the third active pattern ACT3 (e.g., a lower side of the third active pattern ACT3 on the plan view), may be a second contact region. The first contact region may be connected to the one side of the third active pattern ACT3, and be electrically connected to the first transistor T1 and the sixth transistor T6 through a fifth conductive pattern CP5. The second contact region may be connected to an opposite side of the third active pattern ACT3, and be connected to the third semiconductor pattern SCP3 of the fourth transistor T4.

The fifth conductive pattern CP5 may be configured with the fourth conductive layer CL4. One end of the fifth conductive pattern CP5 may be electrically connected to the first contact region of the third transistor T3 through a second contact portion CNT2 penetrating the sixth insulating layer INS6 and the fifth insulating layer INS5. An opposite end of the fifth conductive pattern CP5 may be electrically connected to one region of the first semiconductor pattern SCP1 shared by the first transistor T1 and the sixth transistor T6 through a first contact portion CNT1 penetrating the sixth insulating layer INS6, the fifth insulating layer INS5, the fourth insulating layer INS4, the third insulating layer INS3, and the second insulating layer INS2.

The third gate electrode may be one region of the ninth line WL9 overlapping with the third active pattern ACT3.

The fourth transistor T4 may include a fourth active pattern ACT4 and a fourth gate electrode.

The fourth active pattern ACT4 is one region of a third semiconductor pattern SCP3 overlapping with the tenth line WL10, and may constitute a channel region of the fourth transistor T4. The third semiconductor pattern SCP3 may be configured with the second semiconductor layer.

One region of the third semiconductor pattern SCP3, which does not overlap with the tenth line WL10 and is connected to one side of the fourth active pattern ACT4 (e.g., an upper side of the fourth active pattern ACT4 in a plan view), may be a first contact region, and one region of the third semiconductor pattern SCP3, which does not overlap with the ninth line WL9 and is connected to an opposite side of the fourth active pattern ACT4 (e.g., a lower side of the fourth active pattern ACT4 on the plan view), may be a second contact region. The first contact region may be connected to the one side of the fourth active pattern ACT4, and be connected to the third semiconductor pattern SCP3 of the third transistor T3. The second contact region may be connected to an opposite side of the fourth active pattern ACT4, and be electrically connected to the fourteenth line WL14 configured with the fourth conductive layer CL4 through a corresponding second contact portion CNT2 penetrating the sixth insulating layer INS6 and the fifth insulating layer INS5.

The fourth gate electrode may be one region of the tenth line WL10 overlapping with the fourth active pattern ACT4.

The fifth transistor T5 may include a fifth active pattern ACT5 and a fifth gate electrode.

The fifth active pattern ACT5 is one region of the first semiconductor pattern SCP1 overlapping with the third line WL3, and may constitute a channel region of the fifth transistor T5. The first semiconductor pattern SCP1 may be configured with the first semiconductor layer.

One region of the first semiconductor pattern SCP1, which does not overlap with the third line WL3 and is connected to one side of the fifth active pattern ACT5 (e.g., an upper side of the fifth active pattern ACT5 in a plan view), may be a first contact region, and one region of the first semiconductor pattern SCP1, which does not overlap with the third line WL3 and is connected to an opposite side of the fifth active pattern ACT5 (e.g., a lower side of the fifth active pattern ACT5 on the plan view), may be a second contact region. The first contact region may be connected to the one side of the fifth active pattern ACT5, and be electrically connected to a first conductive pattern CP1 through a corresponding first contact portion CNT1. The second contact region may be connected to an opposite side of the fifth active pattern ACT5, and be connected to the first semiconductor pattern SCP1 of each of the first and second transistors T1 and T2.

The fifth gate electrode may be one region of the third line WL3 overlapping with the fifth active pattern ACT5.

The sixth transistor T6 may include a sixth active pattern ACT6 and a sixth gate electrode.

The sixth active pattern ACT6 is one region of the first semiconductor pattern SCP1 overlapping with the third line WL3, and may be a channel region of the sixth transistor T6. The first semiconductor pattern SCP1 may be configured with the first semiconductor layer.

One region of the first semiconductor pattern SCP1, which does not overlap with the third line WL3 and is connected to one side of the sixth active pattern ACT6 (e.g., an upper side of the sixth active pattern ACT6 in a plan view), may be a first contact region, and one region of the first semiconductor pattern SCP1, which does not overlap with the third line WL3 and is connected to an opposite side of the sixth active pattern ACT6 (e.g., a lower side of the sixth active pattern ACT6 on the plan view), may be a second contact region. The first contact region may be connected to each of the one side of the sixth active pattern ACT6 and a first semiconductor pattern SCP1 of the seventh transistor T7. The second contact region may be connected to each of an opposite side of the sixth active pattern ACT6 and the first semiconductor pattern SCP1 of the first transistor T1. Also, the second contact region may be electrically connected to the fifth conductive pattern CP5 through a corresponding first contact portion CNT1.

The sixth gate electrode may be one region of the third line WL3 overlapping with the sixth active pattern ACT6.

The seventh transistor T7 may include a seventh active pattern ACT7 and a seventh gate electrode.

The seventh active pattern ACT7 may be one region of the first semiconductor pattern SCP1 overlapping with the first line WL1. The first semiconductor pattern SCP1 may be configured with the first semiconductor layer. The seventh active pattern ACT7 may be a channel region of the seventh transistor T7.

One region of the first semiconductor pattern SCP1, which does not overlap with the first line WL1 and is connected to one side of the seventh active pattern ACT7 (e.g., a lower side of the seventh active pattern ACT7 in a plan view), may be a first contact region, and one region of the first semiconductor pattern SCP1, which does not overlap with the first line WL1 and is connected to an opposite side of the seventh active pattern ACT7 (e.g., an upper side of the seventh active pattern ACT7 on the plan view), may be a second contact region. The first contact region may be connected to the one side of the seventh active pattern ACT7, be connected to the first semiconductor pattern SCP1 of the sixth transistor T6, and be electrically connected to a fourth conductive pattern CP4. The second contact region may be connected to an opposite side of the seventh active pattern ACT7, and be electrically connected to a seventh conductive pattern CP7.

The fourth conductive pattern CP4 may be configured with the fourth conductive layer CL4. The fourth conductive pattern CP4 may be electrically connected to the first semiconductor pattern SCP1 of the seventh transistor T7 through a corresponding first contact portion CNT1 penetrating the sixth insulating layer INS6, the fifth insulating layer INS5, the fourth insulating layer INS4, the third insulating layer INS3, and the second insulating layer INS2. Also, the fourth conductive pattern CP4 may be electrically connected to a first connection pattern CNP1.

The first connection pattern CNP1 may be configured with the fifth conductive layer CL5. One end of the first connection pattern CNP1 may be electrically connected to the fourth conductive pattern CP4 through a corresponding first via hole VIH1 penetrating the seventh insulating layer INS7. In addition, an opposite end of the first connection pattern CNP1 may be electrically connected to a first bridge pattern BRP1 configured with the sixth conductive layer CL6 through a corresponding second via hole VIH2.

The first bridge pattern BRP1 may be configured with the sixth conductive layer CL6. The first bridge pattern BRP1 may be electrically connected to the first connection pattern CNP1 through a corresponding second via hole VIH2 penetrating the eighth insulating layer INS8. The first bridge pattern BRP1 may be electrically connected to the first semiconductor pattern SCP1 of the seventh transistor T7 and the first semiconductor pattern SCP1 of the sixth transistor T6 through the first connection pattern CNP1 and the fourth conductive pattern CP4. In embodiments, the first bridge pattern BRP1 may be electrically connected to an anode electrode (refer to “AE” shown in FIG. 7) of a light-emitting element (refer to “LED” shown in FIG. 7) through a third via hole (refer to “VIH3” shown in FIG. 7) penetrating the ninth insulating layer INS9.

The seventh conductive pattern CP7 may be configured with the fourth conductive layer CL4. The seventh conductive pattern CP7 may be electrically connected to the first semiconductor pattern SCP1 of the seventh transistor T7 through a first contact portion CNT1 penetrating the sixth insulating layer INS6, the fifth insulating layer INS5, the fourth insulating layer INS4, the third insulating layer INS3, and the second insulating layer INS2. Also, the seventh conductive pattern CP7 may be electrically connected to the eighth line WL8 through a second contact portion CNT2 penetrating the sixth insulating layer INS6, the fifth insulating layer INS5, and the fourth insulating layer INS4.

The seventh gate electrode may be one region of the first line WL1 overlapping with the seventh active pattern ACT7.

The eighth transistor T8 may include an eighth active pattern ACT8 and an eighth gate electrode.

The eighth active pattern ACT8 may be one region of a first semiconductor pattern SCP1 overlapping with the first line WL1. The first semiconductor pattern SCP1 may be configured with the first semiconductor layer. The eighth active pattern ACT8 may be a channel region of the eighth transistor T8.

One region of the first semiconductor pattern SCP1, which does not overlap with the first line WL1 and is connected to one side of the eighth active pattern ACT8 (e.g., an upper side of the eighth active pattern ACT8 in a plan view), may be a first contact region, and one region of the first semiconductor pattern SCP1, which does not overlap with the first line WL1 and is connected to an opposite side of the eighth active pattern ACT8 (e.g., a lower side of the eighth active pattern ACT8 on the plan view), may be a second contact region. The first contact region may be connected to the one side of the eighth active pattern ACT8, and be electrically connected to the thirteenth line WL13. The second contact region may be connected to an opposite side of the eighth active pattern ACT8, and be electrically connected to a second conductive pattern CP2.

The thirteenth line WL13 configured with the fourth conductive layer CL4 may be electrically connected to the first contact region of the first semiconductor pattern SCP1 of the eighth transistor T8 through a first contact portion CNT1 penetrating the sixth insulating layer INS6, the fifth insulating layer INS5, the fourth insulating layer INS4, the third insulating layer INS3, and the second insulating layer INS2.

The second conductive pattern CP2 may be configured with the fourth conductive layer CL4 to be electrically connected to the second contact region of the first semiconductor pattern SCP1 of the eighth transistor T8 through a first contact portion CNT1 penetrating the sixth insulating layer INS6, the fifth insulating layer INS5, the fourth insulating layer INS4, the third insulating layer INS3, and the second insulating layer INS2. Also, the second conductive pattern CP2 may be electrically connected to the first semiconductor pattern SCP1 of the fifth transistor T5 through a first contact portion penetrating the sixth insulating layer INS6, the fifth insulating layer INS5, the fourth insulating layer INS4, the third insulating layer INS3, and the second insulating layer INS2.

The eighth gate electrode may be one region of the first line WL1 overlapping with the eighth active pattern ACT8.

The storage capacitor Cst may include the lower electrode LE and an upper electrode UE.

The lower electrode LE may be unitary with the first gate electrode GE1. The lower electrode LE may be configured with the first conductive layer CL1.

The upper electrode UE may overlap with the lower electrode LE, and be configured with the second conductive layer CL2. The upper electrode UE may define an opening OPN in which a portion thereof is removed. One region of the lower electrode LE overlapping with the upper electrode UE may be exposed by the opening OPN. The upper electrode UE may be electrically connected to the first conductive pattern CP1.

The first sensor circuit SC1 may be disposed between the first pixel circuit PXC1 and the second pixel circuit PXC2.

The first sensor circuit SC1 may include a ninth transistor T9, the tenth transistor T10, and an eleventh transistor T11.

The ninth transistor T9 may include a ninth active pattern ACT9 and a ninth gate electrode GE9.

The ninth active pattern ACT9 may be one region of a second semiconductor pattern SCP2 overlapping with the ninth gate electrode GE9. The second semiconductor pattern SCP2 may be configured with the first semiconductor layer. The second semiconductor pattern SCP2 may be spaced apart from the first semiconductor pattern SCP1. The ninth active pattern ACT9 may be a channel region of the ninth transistor T9.

One region of the second semiconductor pattern SCP2, which does not overlap with the ninth gate electrode GE9 and is connected to one side of the ninth active pattern ACT9 (e.g., a right side of the ninth active pattern ACT9 in a plan view) may be a first contact region. One region of the second semiconductor pattern SCP2, which does not overlap with the ninth gate electrode GE9 and is connected to an opposite side of the ninth active pattern ACT9 (e.g., a left side of the ninth active pattern ACT9 on the plan view) may be a second contact region. The first contact region may be connected to the one side of the ninth active pattern ACT9, and be electrically connected to a ninth conductive pattern CP9. The second contact region may be connected to each of the one side of the ninth active pattern ACT9 and a second semiconductor pattern SCP2 of the eleventh transistor T11.

The ninth conductive pattern CP9 may be disposed in the first light-sensing pixel PSR1, and be configured with the fourth conductive layer CL4. The ninth conductive pattern CP9 may be electrically connected to the first contact region of the ninth transistor T9 through a first contact portion CNT1 penetrating the sixth insulating layer INS6, the fifth insulating layer INS5, the fourth insulating layer INS4, the third insulating layer INS3, and the second insulating layer INS2. Also, the ninth conductive pattern CP9 may be electrically connected to the eighth line WL8 through a second contact portion penetrating the sixth insulating layer INS6.

The ninth gate electrode GE9 may overlap with the ninth active pattern ACT9, and be configured with the first conductive layer CL1. The ninth gate electrode GE9 may be a conductive pattern having an island shape. The ninth gate electrode GE9 may be electrically connected to the tenth transistor T10 through a tenth conductive pattern CP10.

The tenth conductive pattern CP10 may be configured with the fourth conductive layer CL4. One end of the tenth conductive pattern CP10 may be electrically connected to the ninth gate electrode GE9 through a first contact portion CNT1 penetrating the sixth insulating layer INS6, the fifth insulating layer INS5, the fourth insulating layer INS4, the third insulating layer INS3, and the second insulating layer INS2. An opposite end of the tenth conductive pattern CP10 may be electrically connected to the fourth semiconductor pattern SCP4 of the tenth transistor T10 through a second contact portion CNT2 penetrating the sixth insulating layer INS6 and the fifth insulating layer INS5. Also, the tenth conductive pattern CP10 may be electrically connected to a third connection pattern CNP3 through a first via hole VIH1.

The third connection pattern CNP3 may be configured with the fifth conductive layer CL5. The third connection pattern CNP3 may be electrically connected to the tenth conductive pattern CP10 through a corresponding first via hole VIH1 penetrating the seventh insulating layer INS7. Also, the third connection pattern CNP3 may be electrically connected to a second bridge pattern BRP2 through a second via hole VIH2.

The second bridge pattern BRP2 may be configured with the sixth conductive layer CL6. The second bridge pattern BRP2 may be electrically connected to the third connection pattern CNP3 through a corresponding second via hole VIH2 penetrating the eighth insulating layer INS8. The second bridge pattern BRP2 may be electrically connected to the ninth gate electrode GE9 of the ninth transistor T9 and the fourth semiconductor pattern SCP4 of the tenth transistor T10 through the third connection pattern CNP3 and the tenth conductive pattern CP10.

The second bridge pattern BRP2 may be electrically connected to a first electrode (refer to “EL1” shown in FIG. 7) of a light-receiving element (refer to “LRD” shown in FIG. 7) of the first sensor circuit SC1. The second bridge pattern BRP2 may be formed through the same process as the first and third bridge patterns BRP1 and BRP3, to include the same material as that of the first and third bridge patterns BRP1 and BRP3 and to be provided in the same layer as the first and third bridge patterns BRP1 and BRP3.

The tenth transistor T10 may include a tenth active pattern ACT10 and a tenth gate electrode.

The tenth active pattern ACT10 may be one region of the fourth semiconductor pattern SCP4 overlapping with the eleventh line WL11. The fourth semiconductor pattern SCP4 may be configured with the second semiconductor layer. The fourth semiconductor pattern SCP4 may be spaced apart from the third semiconductor pattern SCP3. The tenth active pattern ACT10 may be a channel region of the tenth transistor T10.

One region of the fourth semiconductor pattern SCP4, which does not overlap with the eleventh line WL11 and is connected to one side of the tenth active pattern ACT10 (e.g., an upper side of the tenth active pattern ACT10 in a plan view), may be a first contact region. One region of the fourth semiconductor pattern SPC4, which does not overlap with the eleventh line WL11 and is connected to an opposite side of the tenth active pattern ACT10 (e.g., a lower side of the tenth active pattern ACT10 on the plan view), may be a second contact region. The first contact region may be connected to the one side of the tenth active pattern ACT10, and be electrically connected to the fifteenth line WL15 through a second contact portion CNT2 penetrating the sixth insulating layer INS6 and the fifth insulating layer INS5. The second contact region may be connected to an opposite side of the tenth active pattern ACT10, and be electrically connected to the ninth gate electrode GE9 of the ninth transistor T9.

The tenth gate electrode may be one region of the eleventh line WL11 overlapping with the tenth active pattern ACT10.

The eleventh transistor T11 may have a dual gate structure in which sub-transistors are connected in series so as to prevent a leakage current. In an embodiment, the eleventh transistor T11 may include the 11ath transistor T11a and the 11bth transistor T11b, for example.

The 11ath transistor T11a may include an 11ath active pattern ACT11a and the 11ath gate electrode.

The 11ath active pattern ACT11a may be one region of a second semiconductor pattern SCP2 overlapping with the second line WL2. The second semiconductor pattern SCP2 may be configured with the first semiconductor layer. The 11ath active pattern ACT11a may be a channel region of the 11ath transistor T11a.

One region of the second semiconductor pattern SCP2, which does not overlap with the second line WL2 and is connected to one side of the 11ath active pattern ACT11a (e.g., an upper side of the 11ath active pattern ACT11a in a plan view), may be a first contact region. One region of the second semiconductor pattern SCP2, which does not overlap with the second line WL2 and is connected to an opposite side of the 11ath active pattern ACT11a (e.g., a lower side of the 11ath active pattern ACT11a on the plan view), may be a second contact region. The first contact region may be connected to each of the one side of the 11ath active pattern ACT11a and the second semiconductor pattern SCP2 of the ninth transistor T9. The second contact region may be connected to each of an opposite side of the 11ath active pattern ACT11a and a second semiconductor pattern SCP2 of the 11bth transistor T11b.

The 11ath gate electrode may be one region of the second line WL2 overlapping with the 11ath active pattern ACT11a.

The 11bth transistor T11b may include an 11bth active pattern ACT11b and the 11bth gate electrode.

The 11bth active pattern ACT11b may be one region of the second semiconductor pattern SCP2 overlapping with the protrusion portion protruding in the second direction DR2 in the second line WL2 extending along the first direction DR1. The second semiconductor pattern SCP2 may be configured with the first semiconductor layer. The 11bth active pattern ACT11b may be a channel region of the 11bth transistor T11b.

One region of the second semiconductor pattern SCP2, which does not overlap with the protrusion portion of the second line WL2 and is connected to one side of the 11bth active pattern ACT11b (e.g., a left side of the 11bth active pattern ACT11b in a plan view), may be a first contact region. One region of the second semiconductor pattern SCP2, which does not overlap with the protrusion portion of the second line WL2 and is connected to an opposite side of the 11bth active pattern ACT11b (e.g., a right side of the 11bth active pattern ACT11b on the plan view), may be a second contact region. The first contact region may be connected to each of the one side of the 11bth active pattern ACT11b and the second semiconductor pattern SCP2 of the 11ath transistor T11a. The second contact region may be connected to an opposite side of the 11bth active pattern ACT11b, and be electrically connected to the seventeenth line WL17 (or readout line) through the eighth conductive pattern CP8.

In accordance with the above-described embodiment, the first data line D1 may be disposed at one edge of a first sub-pixel area in which the first sub-pixel SPX1 is disposed (e.g., a left edge of the first sub-pixel SPX1 in a plan view). The second data line D2 may be disposed at one edge of a second sub-pixel area in which the second sub-pixel SPX is disposed (e.g., a right edge of the second sub-pixel SPX2 on the plan view). In a plan view, the first sensor circuit SC1 (or the seventeenth line WL17) may be disposed between the first data line D1 and the second data line D2. The first pixel circuit PXC1 may be disposed between the first data line D1 and the first sensor circuit SC1 (or the seventeenth line WL17), and the second pixel circuit PXC2 may be disposed between the first sensor circuit SC1 (or the seventeenth line WL17) and the second data line D2. Accordingly, a separation distance between each of the first and second data lines D1 and D2 and the first sensor circuit SC1 (or the seventeenth line WL17) may be further secured. Thus, a coupling capacitance generated between the first data line D1 and the readout line (or the seventeenth line WL17) and between the second data line D2 and the readout line may be further reduced or be further prevented.

In the above-described embodiment, it has been described the eighteenth line WL18 is disposed in the same layer as the seventeenth line WL17 (or readout line). However, the disclosure is not limited thereto. In some embodiments, the eighteenth line WL18 may be disposed in the same layer as the first and second data lines D1 and D2.

FIG. 18 is a schematic plan view illustrating an embodiment of sub-pixels and light-sensing pixels, which are disposed in one area of a display area DA of a display device in accordance with the disclosure.

In FIG. 18, for convenience of description, only components included in a fourth conductive layer, a fifth conductive layer CL5, and a sixth conductive layer CL6 in sub-pixels and light-sensing pixels, which are arranged on the same pixel row (e.g., a first pixel row) are illustrated.

In FIG. 18, portions different from the portions of the above-described embodiment will be mainly described to avoid redundancy.

Referring to FIG. 18, in the display area DA, a first sub-pixel SPX1, a second sub-pixel SPX2, a third sub-pixel SPX3, a fourth sub-pixel SPX4, a fifth sub-pixel SPX5, and a sixth sub-pixel SPX6 may be arranged along the first direction DR1. A first light-sensing pixel PSR1 may be disposed between the first sub-pixel SPX1 and the second sub-pixel SPX2, and a second light-sensing pixel PSR2 may be disposed between the fifth sub-pixel SPX5 and the sixth sub-pixel SPX6.

The first sub-pixel SPX1 may include a first pixel circuit PXC1, the second sub-pixel SPX2 may include a second pixel circuit PXC2, the third sub-pixel SPX3 may include a third pixel circuit PXC3, the fourth sub-pixel SPX4 may include a fourth pixel circuit PXC, the fifth sub-pixel SPX5 may include a fifth pixel circuit PXC5, and the sixth sub-pixel SPX6 may include a sixth pixel circuit PXC6. The first light-sensing pixel PSR1 may include a first sensor circuit SC1, and the second light-sensing pixel PSR2 may include a second sensor circuit SC2. The first pixel circuit PXC1 and the fifth pixel circuit PXC5 may be substantially the same, and the first sensor circuit SC1 and the second sensor circuit SC2 may be substantially the same.

The first sensor circuit SC1 may be disposed between the first pixel circuit PXC1 and the second pixel circuit PXC2, and the second sensor circuit SC2 may be disposed between the fifth pixel circuit PXC5 and the sixth pixel circuit PXC6. The first pixel circuit PXC1 and the second pixel circuit PXC2, which have the first sensor circuit SC1 interposed therebetween, may be mirror-symmetrical to each other, and substantially have the same structure. The fifth pixel circuit PXC5 and the sixth pixel circuit PXC6, which have the second sensor circuit SC2 interposed therebetween, may be mirror-symmetrical to each other, and substantially have the same structure. The third pixel circuit PXC3 and the fourth pixel circuit PXC4 may be mirror-symmetrical to each other, and substantially have the same structure. In embodiments, the first to sixth pixel circuits PXC1 to PXC6 may have structures substantially similar or identical to one another.

A data line may be disposed one side of each of odd-numbered sub-pixels, e.g., the first, third, and fifth sub-pixels SPX1, SPX3, and SPX5 (e.g., a left side of each of the first, third, and fifth sub-pixels SPX1, SPX3, and SPX5 in a plan view). In an embodiment, in a plan view, a first data line D1 may be disposed at a left side of the first sub-pixel SPX1, a third data line D3 may be disposed at a left side of the third sub-pixel SPX3, and a fifth data line D5 may be disposed at a left side of the fifth sub-pixel SPX5, for example. A data line may be disposed one side of each of even-numbered sub-pixels, e.g., the second and fourth sub-pixels SPX2 and SPX4 (e.g., a right side of each of the second and fourth sub-pixels SPX2 and SPX4 on the plan view). In an embodiment, in a plan view, a second data line D2 may be disposed at a right side of the second sub-pixel SPX2, and a fourth data line D4 may be disposed at a right side of the fourth sub-pixel SPX4, for example.

In embodiments, the second data line D2 and the third data line D3 may be disposed immediately adjacent to each other in the first direction DR1, and the fourth data line D4 and the fifth data line D5 may be disposed immediately adjacent to each other in the first direction DR1. No pixel circuit may be disposed in an area in which two data lines are disposed immediately adjacent to each other. In an embodiment, no pixel circuit may be disposed between the second data line D2 and the third data line D3 and between the fourth data line D4 and the fifth data line D5, for example.

A nineteenth line WL19 may be disposed between the third sub-pixel SPX3 and the fourth sub-pixel SPX4. The nineteenth line WL19 may extend in the second direction DR2, and be configured with the sixth conductive layer CL6. The nineteenth line WL19 may be formed through the same process as the first to fifth data lines D1 to D5, to include the same material as that of the first to fifth data lines D1 to D5 and to be provided in the same layer as the first to fifth data lines D1 to D5. Also, the nineteenth line WL19 may be spaced apart from the first to fifth data lines D1 to D5. The nineteenth line WL19 may be electrically connected to a fourth connection pattern CNP4 through a second via hole VIH2 penetrating an eighth insulating layer (refer to “INS8” shown in FIG. 17).

The fourth connection pattern CNP4 may be configured with the fifth conductive layer CL5, and be disposed between the third sub-pixel SPX3 and the fourth sub-pixel SPX4. One end of the fourth connection pattern CNP4 may be electrically connected to the nineteenth line WL19 through the corresponding second via hole VIH2. An opposite end of the fourth connection pattern CNP4 may be electrically connected to a fourteenth line WL14 (or first initialization power line) through a first via hole VIH1 penetrating a seventh insulating layer (refer to “INS7” shown in FIG. 17). In embodiments, the nineteenth line WL19 may be electrically connected to the fourteenth line WL14 through the fourth connection pattern CNP4. Accordingly, the nineteenth line WL19 may be supplied with the first initialization power voltage (refer to “Vint1” shown in FIG. 6).

In embodiments, the nineteenth line WL19 may be an additional line AWL of the second power line (refer to “PL2” shown in FIG. 6) to which the first initialization power voltage Vint1 is applied. The fourteenth line WL14 which extends in the first direction DR1 and is configured with a fourth conductive layer (refer to “CL4” shown in FIG. 17) may be a horizontal power line of the second power line PL2, an eighteenth line WL18 (or vertical dummy line DML_V) which extends in the second direction DR2 and is configured with the fifth conductive layer CL5 may be a first vertical power line of the second power line PL2, and the nineteenth line WL19 (or additional line AWL) which extends in the second direction DR2 and is configured with the sixth conductive layer CL6 may be a second vertical power line of the second power line PL2. The fourteenth line WL14, the eighteenth line WL18, and the nineteenth line WL19, which are disposed in different layers, may be electrically connected to each other, to form the second power line PL2 having a mesh structure. As described above, the second power line PL2 may be implemented as a triple-layer including the fourteenth line WL14 configured with the fourth conductive layer CL4, the eighteenth line WL18 configured with the fifth conductive layer CL5, and the nineteenth line WL19 configured with the sixth conductive layer CL6. Accordingly, the line resistance of the second power line PL2 may be reduced.

In the above-described embodiment, it has been described that the nineteenth line WL19 as the additional line AWL is electrically connected to the fourteenth line WL14 supplied with the first initialization power voltage Vint1. However, the disclosure is not limited thereto. In some embodiments, the additional line AWL may be electrically connected to an eight line WL8 and/or a twelfth line WL12, supplied with the second initialization power voltage (refer to “Vint2” shown in FIG. 6), to reduce the line resistance of the eighth line WL8 and/or the twelfth line WL12. Also, it has been described that the nineteenth line WL19 (or additional line AWL) is disposed between the third sub-pixel SPX3 and the fourth sub-pixel SPX4. However, the disclosure is not limited thereto, and the position of the nineteenth line WL19 may be variously changed.

In the above-described embodiment, it has been described that the eighteenth line WL18 as the vertical dummy line DML_V is electrically connected to the fourteenth line WL14 to be supplied with the first initialization power voltage Vint1. However, the disclosure is not limited thereto. In some embodiments, the eighteenth line WL18 may be electrically connected to at least one of a sixth line (refer to “WL6” shown in FIG. 9) supplied with the second power voltage (refer to “VSS” shown in FIG. 6) having a constant voltage level and the eighth line WL8 supplied with the second initialization power voltage Vint2, to be used as a shielding member which reduces a coupling capacitance generated between a seventeenth line WL17 and the second pixel circuit PXC2.

FIG. 19 is a schematic diagram illustrating an embodiment of a connection relationship of some lines in one area of a display area DA of a display device in accordance with the disclosure.

In FIG. 19, for convenience of description, only some signal lines in sub-pixels and light-sensing pixels, which are arranged on each of first to fourth pixel rows R1 to R4 are illustrated.

In FIG. 19, portions different from the portions of the above-described embodiment will be mainly described to avoid redundancy.

Referring to FIG. 19, the display area DA may be divided into pixel rows R1 to R4. The pixel rows R1 to R4 may extend in the first direction DR1, and be arranged in the second direction R2. Each of the pixel rows R1 to R4 may include first to sixth sub-pixels SPX1 to SPX6. Each of the first to sixth sub-pixels SPX1 to SPX6 may include a pixel circuit. Also, each of the first to sixth sub-pixels SPX1 to SPX6 may include first and second light-sensing pixels PSR1 and PSR2. Each of the first and second light-sensing pixels PSR1 and PSR2 may include a sensor circuit.

In embodiments, sub-pixels SPX1 to SPX6 may be arranged with respect to the first direction DR1 in an order of a first sub-pixel SPX1, a second sub-pixel SPX2, a third sub-pixel SPX3, a fourth sub-pixel SPX4, a fifth sub-pixel SPX5, and a sixth sub-pixel SPX6 on each of first to fourth pixel rows R1 to R4. On each of the first to fourth pixel rows R1 to R4, a first light-sensing pixel PSR1 may be disposed between the first sub-pixel SPX1 and the second sub-pixel SPX2, and a second light-sensing pixel PSR2 may be disposed between the fifth sub-pixel SPX5 and the sixth sub-pixel SPX6.

Pixel circuits PXC11 to PXC16 corresponding to sub-pixels SPX1 to SPX6 of the first pixel row R1 may be arranged in the first direction DR1 on the first pixel row R1. Sensor circuits SC11 and SC12 corresponding to light-sensing pixels PSR1 and PSR2 of the first pixel row R1 may be arranged in the first direction DR1 on the first pixel row R1.

Pixel circuits PXC21 to PXC26 corresponding to sub-pixels SPX1 to SPX6 of the second pixel row R2 may be arranged in the first direction DR1 on the second pixel row R2. Sensor circuits SC21 and SC22 corresponding to light-sensing pixels PSR1 and PSR2 of the second pixel row R2 may be arranged in the first direction DR1 on the second pixel row R2.

Pixel circuits PXC31 to PXC36 corresponding to sub-pixels SPX1 to SPX6 of the third pixel row R3 may be arranged in the first direction DR1 on the third pixel row R3. Sensor circuits SC31 and SC32 corresponding to light-sensing pixels PSR1 and PSR2 of the third pixel row R3 may be arranged in the first direction DR1 on the third pixel row R3.

Pixel circuits PXC41 to PX46 corresponding to sub-pixels SPX1 to SPX6 of the fourth pixel row R4 may be arranged in the first direction DR1 on the fourth pixel row R4. Sensor circuits SC41 and SC42 corresponding to light-sensing pixels PSR1 and PSR2 of the fourth pixel row R4 may be arranged in the first direction DR1 on the fourth pixel row R4.

A fourteenth line WL14 and a horizontal dummy line DML_H may be disposed on each of the first to fourth pixel rows R1 to R4. The fourteenth line WL14 may be the second power line PL2 (or first initialization power line) described with reference to FIG. 6, and the horizontal dummy line DML_H may be the sixth line WL6 described with reference to FIGS. 9 to 17. The fourteenth line WL14 may be supplied with the first initialization power voltage (refer to “Vint1” shown in FIG. 6), and the horizontal dummy line DML_H may be supplied with the second power voltage (refer to “VSS” shown in FIG. 6).

A first data line D1 may be disposed in the first sub-pixels SPX1 of the first to fourth pixel rows R1 to R4. A second data line D2 may be disposed in the second sub-pixels SPX2 of the first to fourth pixel rows R1 to R4. A third data line D3 may be disposed in the third sub-pixels SPX3 of the first to fourth pixel rows R1 to R4. A fourth data line D4 may be disposed in the fourth sub-pixels SPX4 of the first to fourth pixel rows R1 to R4. A fifth data line D5 may be disposed in the fifth sub-pixels SPX5 of the first to fourth pixel rows R1 to R4. A sixth data line D6 may be disposed in the sixth sub-pixels SPX6 of the first to fourth pixel rows R1 to R4.

A first readout line RX1 and a first vertical dummy line DML_V1 may be disposed in the first light-sensing pixels PSR1 of the first to fourth pixel rows R1 to R4. In a plan view, the first readout line RX1 and the first vertical dummy line DML_V1 may be disposed between the first data line D1 and the second data line D2. In a plan view, a pixel circuit of the first sub-pixel SPX1 may be disposed between the first data line D1 and the first readout line RX1, and a pixel circuit of the second sub-pixel SPX2 may be disposed between the first readout line RX1 and the second data line D2. On each of the first to fourth pixel rows R1 to R4, the first vertical dummy line DML_V1 may be electrically connected to the fourteenth line WL14 (or second power line PL2) through a corresponding first connection member CM1.

A second readout line RX2 and a second vertical dummy line DML_V2 may be disposed in the second light-sensing pixels PSR2 of the first to fourth pixel rows R1 to R4. In a plan view, the second readout line RX2 and the second vertical dummy line DML_V2 may be disposed between the fifth data line D5 and the sixth data line D6. In a plan view, a pixel circuit of the fifth sub-pixel SPX5 may be disposed between the fifth data line D5 and the second readout line RX2, and a pixel circuit of the sixth sub-pixel SPX6 may be disposed between the second readout line RX2 and the sixth data line D6. On each of the first to fourth pixel rows R1 to R4, the second vertical dummy line DML_V2 may be electrically connected to the fourteenth line WL14 (or second power line PL2) through a corresponding first connection member CM1.

In embodiments, an additional line AWL may be disposed between the third sub-pixels SPX3 and the fourth sub-pixels SPX4 of the first to fourth pixel rows R1 to R4. On each of the first to fourth pixel rows R1 to R4, the additional line AWL may be electrically connected to the fourteenth line WL14 through a corresponding second connection member CM2.

Each of the first and second vertical dummy lines DML_V1 and DML_V2 may be electrically connected to the fourteenth line WL14 through a corresponding first connection member CM1, and the additional line AWL may be electrically connected to the fourteenth line WL14 through a corresponding second connection member CM2. In addition, the first and second vertical dummy lines DML_V1 and DML_V2, the additional line, and the fourteenth line WL14 may be electrically and/or physically separated from the horizontal dummy line DML_H.

As described above, as the pixel circuit of the first sub-pixel SPX1 is disposed between the first data line D1 and the first readout line RX1, the pixel circuit of the second sub-pixel SPX2 is disposed between the first readout line RX1 and the second data line D2, and the first vertical dummy line DML_V1 is disposed between the first readout line RX1 and the pixel circuit of the second sub-pixel SPX2, a coupling capacitance which may be generated between each of the first and second data lines D1 and D2 and the first readout line RX1 may be reduced or prevented.

In addition, as the pixel circuit of the fifth sub-pixel SPX5 is disposed between the fifth data line D5 and the second readout line RX2, the pixel circuit of the sixth sub-pixel SPX6 is disposed between the second readout line RX2 and the sixth data line D6, and the second vertical dummy line DML_V2 is disposed between the second readout line RX2 and the pixel circuit of the sixth sub-pixel SPX6, a coupling capacitance which may be generated between each of the fifth and sixth data lines D5 and D6 and the second readout line RX2 may be reduced or prevented.

In the above-described embodiment, it has been described that the first and second vertical dummy lines DML_V1 and DML_V2 are electrically connected to the fourteenth line WL14. However, the disclosure is not limited thereto. In some embodiments, the first vertical dummy line DML_V1 among the first and second vertical dummy lines DML_V1 and DML_V2 may be electrically connected to the fourteenth line WL14, and the second vertical dummy line DML_V2 among the first and second vertical dummy lines DML_V1 and DML_V2 may be electrically connected to another line, e.g., the horizontal dummy line DML_H or a power line supplied with the second initialization power voltage (refer to “Vint2” shown in FIG. 6).

FIG. 20 is a schematic plan view illustrating an embodiment of a first light-sensing pixel PSR1 disposed in one area of a display area DA of a display device in accordance with the disclosure. FIG. 21 is a schematic cross-sectional view taken along line II-II′ shown in FIG. 20.

The embodiment shown in FIG. 20 may be configured substantially identical or similar to the first light-sensing pixel PSR1 shown in FIG. 9, except that a sixth line WL6 (or horizontal dummy line DML_H) and an eighteenth line WL18 (or vertical dummy line DML_V) are electrically connected to each other.

Therefore, in relation to the first light-sensing pixel PSR1 shown in FIGS. 20 and 21, portions different from the portions of the above-described embodiment will be mainly described to avoid redundancy.

Referring to FIGS. 20 and 21, an eighteenth line WL18 corresponding to a vertical dummy line DML_V may be spaced apart from a seventeenth line WL17 (or readout line). The seventeenth line WL17 and the eighteenth line WL18 may be formed through the same process, to including the same material and to be provided in the same layer. In an embodiment, the seventeenth line WL17 and the eighteenth line WL18 may be configured with a fifth conductive layer CL5, for example.

The eighteenth line WL18 may be electrically connected to an eleventh conductive pattern CP11 through a first via hole VIH1 penetrating a seventh insulating layer INS7.

The eleventh conductive pattern CP11 may be disposed in a first light-sensing pixel PSR1, and be configured with a fourth conductive layer CL4 disposed on a sixth insulating layer INS6. The eleventh conductive pattern CP11 may be electrically connected to a sixth line WL6 through a first contact portion CNT1 penetrating the sixth insulating layer INS6, a fifth insulating layer INS5, a fourth insulating layer INS4, and a third insulating layer INS3.

In embodiments, the sixth line WL6 may be supplied with a low-potential voltage having a constant voltage level, e.g., the second power voltage (refer to “VSS” shown in FIG. 6). The eighteenth line WL18 configured with the fifth conductive layer CL5 may be electrically connected to the sixth line WL6 configured with a second conductive layer CL2 through the first conductive pattern CP11 configured with the fourth conductive layer CL4. Accordingly, the second power voltage VSS may be supplied even to the eighteenth line WL18. The sixth line WL6 may be a horizontal dummy line DML_H extending in the first direction DR1, and the eighteenth line WL18 may be a vertical dummy line DML_V extending in the second direction DR2. The horizontal dummy line DML_H and the vertical dummy line DML_V, which are electrically connected to each other, may constitute a dummy line DML. The dummy line DML may have a mesh structure due to the horizontal dummy line DML_H and the vertical dummy line DML_V.

The dummy line DML may be electrically and/or physically separated from a fourteenth line WL14 to which the first initialization power voltage (refer to “Vint1” shown in FIG. 6) is supplied. That is, the vertical dummy line DML_V (or the eighteenth line WL18) and the horizontal dummy line DML_H (or the sixth line WL6) may be electrically and/or physically separated from the fourteenth line WL14.

In embodiments, the vertical dummy line DML_V supplied with the second power voltage VSS may be disposed between the seventeenth line WL17 corresponding to the readout line and a second pixel circuit PXC2, to reduce or prevent a coupling capacitance which may be generated between the seventeenth line WL17 and the second pixel circuit PXC2. That is, the vertical dummy line DML_V (or the eighteenth line WL18) may be used as a shielding member which reduces or prevents a coupling capacitance generated between the readout line (or the seventeenth line WL17) and the second pixel circuit PXC2.

When the vertical dummy line DML_V (or the eighteenth line WL18) is used as a shielding member, a phenomenon in which a signal (e.g., a sensing signal) applied to the seventeenth line WL17 (or readout line) is influenced by the second pixel circuit PXC2 may be reduced or prevented. Thus, noise occurring in the signal applied to the seventeenth line WL17 due to the second pixel circuit PXC2 may be reduced. Accordingly, fingerprint sensitivity and fingerprint accuracy in the first light-sensing pixel PSR1 are improved, so that the reliability of the display device (refer to “DD” shown in FIG. 1) may be further improved.

FIG. 22 is a schematic plan view illustrating an embodiment of sub-pixels and light-sensing pixels, which are disposed in one area of a display area DA of a display device in accordance with the disclosure.

In FIG. 22, for convenience of description, only components included in a fourth conductive layer, a fifth conductive layer CL5, and a sixth conductive layer CL6 in sub-pixels and light-sensing pixels, which are arranged on the same pixel row (e.g., a first pixel row) are illustrated.

In FIG. 22, portions different from the portions of the above-described embodiment will be mainly described to avoid redundancy.

Referring to FIG. 22, in the display area DA, a first sub-pixel SPX1, a second sub-pixel SPX2, a third sub-pixel SPX3, a fourth sub-pixel SPX4, a fifth sub-pixel SPX5, and a sixth sub-pixel SPX6 may be arranged along the first direction DR1. A first light-sensing pixel PSR1 may be disposed between the first sub-pixel SPX1 and the second sub-pixel SPX2, and a second light-sensing pixel PSR2 may be disposed between the fifth sub-pixel SPX5 and the sixth sub-pixel SPX6.

In embodiments, an eighteenth line WL18 (or vertical dummy line DML_V) spaced apart from a seventeenth line WL17 (or readout line) may be disposed in each of the first and second light-sensing pixels PSR1 and PSR2. The eighteenth line WL18 may be electrically connected to an eleventh conductive pattern CP11, and be electrically connected to the sixth line WL6 (or horizontal dummy line) described with reference to FIG. 20 through the eleventh conductive pattern CP11.

A nineteenth line WL19 may be disposed between the third sub-pixel SPX3 and the fourth sub-pixel SPX4. The nineteenth line WL19 may extend in the second direction DR2, and be configured with a sixth conductive layer CL6. The nineteenth line WL19 may be formed through the same process as first to fifth data lines D1 to D5, to include the same material as that of the first to fifth data lines D1 to D5 and to be provided in the same layer as the first to fifth data lines D1 to D5. Also, the nineteenth line WL19 may be spaced apart from the first to fifth data lines D1 to D5. The nineteenth line WL19 may be electrically connected to a fourth connection pattern CNP4 through a second via hole VIH2 penetrating an eighth insulating layer (refer to “INS8” shown in FIG. 21).

The fourth connection pattern CNP4 may be configured with a fifth conductive layer CL5, and be disposed between the third sub-pixel SPX3 and the fourth sub-pixel SPX4. One end of the fourth connection pattern CNP4 may be electrically connected to the nineteenth line WL19 through the corresponding second via hole VIH2. An opposite end of the fourth connection pattern CNP4 may be electrically connected to a fourteenth line WL14 through a first via hole VIH1 penetrating a seventh insulating layer (refer to “INS7” shown in FIG. 21). In embodiments, the nineteenth line WL19 may be electrically connected to the fourteenth line WL14 through the fourth connection pattern CNP4. Accordingly, the nineteenth line WL19 may be supplied with the first initialization power voltage (refer to “Vint1” shown in FIG. 6).

In embodiments, the nineteenth line WL19 may be an additional line AWL of the second power line (refer to “PL2” shown in FIG. 6) to which the first initialization power voltage Vint1 is applied. The fourteenth line WL14 which extends in the first direction DR1 and is configured with a fourth conductive layer (refer to “CL4” shown in FIG. 21) may be a horizontal power line of the second power line PL2, and the nineteenth line WL19 (or the additional line AWL) which extends in the second direction DR2 and is configured with the sixth conductive layer CL6 may be a vertical power line of the second power line PL2. The fourteenth line WL14 and the nineteenth line WL19, which are disposed in different layers, may be electrically connected to each other, to form the second power line PL2 having a mesh structure. As described above, the second power line PL2 may be implemented as a double-layer including the fourteenth line WL14 configured with the fourth conductive layer CL4 and the nineteenth line WL19 configured with the sixth conductive layer CL6. Accordingly, the line resistance of the second power line PL2 may be reduced.

In embodiments, the nineteenth line WL19 (or the additional line AWL) may be electrically and/or physically separated from the eighteenth line WL18 as the vertical dummy line DML_V.

FIG. 23 is a schematic diagram illustrating an embodiment of a connection relationship of some lines in one area of a display area DA of a display device in accordance with the disclosure.

In FIG. 23, for convenience of description, only some signal lines in sub-pixels and light-sensing pixels, which are arranged on each of first to fourth pixel rows R1 to R4 are illustrated.

In FIG. 23, portions different from the portions of the above-described embodiment will be mainly described to avoid redundancy.

Referring to FIG. 23, a first readout line RX1 and a first vertical dummy line DML_V1 may be disposed in first light-sensing pixels PSR1 of the first to fourth pixel rows R1 to R4. On each of the first to fourth pixel rows R1 to R4, the first vertical dummy line DML_V1 may be electrically connected to a horizontal dummy line DML_H through a corresponding first connection member CM1. The same voltage, e.g., the second power voltage (refer to “VSS” shown in FIG. 6) having a constant voltage level may be supplied to the horizontal dummy line DML_H and the first vertical dummy line DML_V1.

A second readout line RX2 and a second vertical dummy line DML_V2 may be disposed in second light-sensing pixels PSR2 of the first to fourth pixel rows R1 to R4. On each of the first to fourth pixel rows R1 to R4, the second vertical dummy line DML_V2 may be electrically connected to the horizontal dummy line DML_H through a corresponding second connection member CM2. The same voltage, e.g., the second power voltage VSS having a constant voltage level may be supplied to the horizontal dummy line DML_H and the second vertical dummy line DML_V2.

In embodiments, an additional line AWL may be disposed between third sub-pixels SPX3 and fourth sub-pixels SPX4 of the first to fourth pixel rows R1 to R4. On each of the first to fourth pixel rows R1 to R4, the additional line AWL may be electrically connected to a fourteenth line WL14 through a corresponding second connection member CM2. The same voltage, e.g., the first initialization voltage (refer to “Vint1” shown in FIG. 6) having a constant voltage level may be supplied to the additional line AWL and the fourteenth line WL14.

Each of the first and second vertical dummy lines DML_V1 and DML_V2 may be electrically connected to the horizontal dummy line DML_H through a corresponding first connection member CM1, and the additional line AWL may be electrically connected to the fourteenth line WL14 through a corresponding second connection member CM2. The first and second vertical dummy lines DML_V1 and DML_V2 and the horizontal dummy line DML_H may be electrically and/or physically separated from the fourteenth line WL14 and the additional line AWL.

FIG. 24 is a schematic block diagram illustrating an embodiment of an electronic device 1000 in accordance with the disclosure. FIG. 25 is a schematic view illustrating an embodiment in which the electronic device 1000 shown in FIG. 24 is implemented as a smartphone. FIG. 26 is a schematic view illustrating an embodiment in which the electronic device 1000 shown in FIG. 24 is implemented as a tablet personal computer (“PC”).

Referring to FIGS. 24 to 26, the electronic device 1000 may include a processor 1010, a memory device 1020, a storage device 1030, an input/output (“I/O”) device 1040, a power supply 1050, and a display device 1060. The display device 1060 may be the display device DD shown in FIGS. 1 and 2. Also, the electronic device 1000 may further include several ports capable of communicating with a video card, a sound card, a memory card, a universal serial bus (“USB”) device, or the like, or communicating with other systems. In embodiments, as shown in FIG. 25, the electronic device 1000 may be implemented as a smartphone. In another embodiment, as shown in FIG. 26, the electronic device 1000 may be implemented as a tablet PC. However, this is merely illustrative, and the electronic device 1000 is not limited to the above-described example. In an embodiment, the electronic device 1000 may be implemented as a mobile phone, a video phone, a smart pad, a smart watch, a vehicle navigation system, a computer monitor, a notebook computer, a head disposed (e.g., mounted) display device, or the like, for example.

The processor 1010 may perform predetermined calculations or tasks. In some embodiments, the processor 1010 may be a microprocessor, a central processing unit, an application processor, or the like. The processor 1010 may be connected to other components through an address bus, a control bus, a data bus, or the like. In some embodiments, the processor 1010 may be connected to an extension bus such as a peripheral component interconnect (“PCI”) bus.

The memory device 1020 may store data desired for an operation of the electronic device 1000. In an embodiment, the memory device 1020 may include a nonvolatile memory device such as an Erasable Programmable Read-Only Memory (“EPROM”) device, an Electrically Erasable Programmable Read-Only Memory (“EEPROM”) device, a flash memory device, a Phase Change Random Access Memory (“PRAM”) device, a Resistance Random Access Memory (“RRAM”) device, a Nano Floating Gate Memory (“NFGM”) device, a Polymer Random Access Memory (“PoRAM”) device, a Magnetic Random Access Memory (“MRAM”) device, or a Ferroelectric Random Access Memory (“FRAM”) device, and/or a volatile memory device such as a Dynamic Random Access Memory (“DRAM”) device, a Static Random Access Memory (“SRAM”) device, or a mobile DRAM device, for example.

The storage device 1030 may include a Solid State Drive (“SSD”), a Hard Disk Drive (“HDD”), a Compact Disc Read Only Memory (“CD-ROM”), or the like.

The I/O device 1040 may include an input means such as a keyboard, a keypad, a touch screen, or a mouse, and an output means such as a speaker or a printer. In some embodiments, the display device 1060 may be included in the I/O device 1040.

The power supply 1050 may supply power desired for an operation of the electronic device 1000. In an embodiment, the power supply 1050 may be a power management integrated circuit (“PMIC”), for example.

The display device 1060 may display an image corresponding to visual information of the electronic device 1000. The display device 1060 may be an organic light-emitting display device or a quantum dot light-emitting display device, but the disclosure is not limited thereto. The display device 1060 may be connected to other components through the buses or another communication link.

In accordance with the disclosure, a light-sensing pixel is disposed between a first sub-pixel and a second sub-pixel. A readout line electrically connected to a sensor circuit of the light-sensing pixel is disposed between a first data line of the first sub-pixel and a second data line of the second sub-pixel, so that a separation distance between the readout line and the first and second data lines may be secured. Accordingly, a coupling capacitance which may be generated between the readout line and the first and second data lines may be reduced.

In accordance with the disclosure, a vertical dummy line which is configured with the same layer (or conductive layer) as a readout line and is spaced apart from the readout line is further disposed between a light-sensing pixel and a second sub-pixel. The vertical dummy line may reduce a coupling capacitance which may be generated between the readout line and a pixel circuit of the second sub-pixel. Accordingly, the reliability of the display device and the electronic device having the same may be improved.

In accordance with the disclosure, a vertical dummy line is electrically connected to a power line supplied with a voltage having a constant voltage level, to reduce the line resistance of the power line.

Embodiments have been disclosed herein, and although specific terms are employed, they are used and are to be interpreted in a generic and descriptive sense only and not for purpose of limitation. In some instances, as would be apparent to one of ordinary skill in the art as of the filing of the application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the disclosure as set forth in the following claims.

What is claimed is:

1. A display device comprising:
a first sub-pixel and a second sub-pixel, each of the first sub-pixel and the second sub-pixel including a pixel circuit;
a light-sensing pixel disposed between the first sub-pixel and the second sub-pixel, the light-sensing pixel including a sensor circuit;
a horizontal dummy line commonly provided in the first sub-pixel, the second sub-pixel, and the light-sensing pixel, the horizontal dummy line extending in a first direction;
a first data line electrically connected to the first sub-pixel;
a second data line electrically connected to the second sub-pixel;
a readout line electrically connected to the sensor circuit, the readout line extending in a second direction;
a vertical dummy line spaced apart from the readout line; and
an initialization power line supplied with an initialization power voltage, the initialization power line being electrically connected to the pixel circuit,
wherein the readout line and the vertical dummy line are disposed in a same layer, and
wherein the first and second data lines are disposed on the readout line and the vertical dummy line.

2. The display device of claim 1, wherein, in a plan view, the readout line and the vertical dummy line are disposed between the first data line and the second data line.

3. The display device of claim 1, wherein the vertical dummy line is electrically separated from the horizontal dummy line.

4. The display device of claim 1, wherein the vertical dummy line is electrically connected to the initialization power line.

5. The display device of claim 4, wherein the initialization power line extends in the first direction, and the vertical dummy line extends in the second direction so that the initialization power line and the vertical dummy line form a mesh structure.

6. The display device of claim 4, further comprising:
a third sub-pixel and a fourth sub-pixel, disposed adjacent to the second sub-pixel in the first direction;
a third data line electrically connected to the third sub-pixel;
a fourth data line electrically connected to the fourth sub-pixel; and
an additional line disposed between the third sub-pixel and the fourth sub-pixel,
wherein the additional line is disposed in a same layer as the first to fourth data lines.

7. The display device of claim 6, wherein the additional line is electrically connected to the initialization power line.

8. The display device of claim 6, wherein the additional line and the readout line are disposed in different layers.

9. The display device of claim 6, wherein, in a plan view, the additional line is disposed between the third data line and the fourth data line.

10. The display device of claim 9, wherein, in the plan view, the pixel circuit of the first sub-pixel is disposed between the first data line and the sensor circuit, and the pixel circuit of the second sub-pixel is disposed between the second data line and the sensor circuit, and
wherein, in the plan view, a pixel circuit of the third sub-pixel is disposed between the third data line and the additional line, and a pixel circuit of the fourth sub-pixel is disposed between the additional line and the fourth data line.

11. The display device of claim 1, wherein the vertical dummy line is electrically connected to the horizontal dummy line.

12. The display device of claim 11, wherein the vertical dummy line and the horizontal dummy line are supplied with a low-potential driving voltage having a constant level.

13. The display device of claim 12, wherein the horizontal dummy line extends in the first direction, and the vertical dummy line extends in the second direction so that the horizontal dummy line and the vertical dummy line have a mesh structure.

14. The display device of claim 1, wherein each of the first sub-pixel and the second sub-pixel includes a light-emitting element emitting light, and
wherein the light-sensing pixel includes a light-receiving element outputting a sensing signal.

15. The display device of claim 1, further comprising:
first, second, third, fourth, fifth, sixth, seventh, eighth, and ninth insulating layers sequentially disposed on a substrate;
a first conductive layer disposed between the second insulating layer and the third insulating layer;
a second conductive layer disposed between the third insulating layer and the fourth insulating layer;
a third conductive layer disposed between the fifth insulating layer and the sixth insulating layer;
a fourth conductive layer disposed between the sixth insulating layer and the seventh insulating layer;
a fifth conductive layer disposed between the seventh insulating layer and the eighth insulating layer; and
a sixth conductive layer disposed between the eighth insulating layer and the ninth insulating layer,
wherein the second conductive layer includes the horizontal dummy line, the fourth conductive layer includes the initialization power line, the fifth conductive layer includes the readout line and the vertical dummy line, and the sixth conductive layer includes the first and second data lines.

16. A display device comprising:
a first sub-pixel, a second sub-pixel, a third sub-pixel, and a fourth sub-pixel arranged in a first direction, each of the first to fourth sub-pixels including a pixel circuit;
a light-sensing pixel disposed between the first sub-pixel and the second sub-pixel, the light-sensing pixel including a sensor circuit;
a horizontal dummy line commonly provided in the first to fourth sub-pixels and the light-sensing pixel, the horizontal dummy line extending in the first direction;
a first data line electrically connected to the pixel circuit of the first sub-pixel;
a second data line electrically connected to the pixel circuit of the second sub-pixel;
a third data line electrically connected to the pixel circuit of the third sub-pixel;
a fourth data line electrically connected to the pixel circuit of the fourth sub-pixel;
a readout line electrically connected to the sensor circuit, the readout line extending in a second direction;
a vertical dummy line spaced apart from the readout line;
an initialization power line supplied with an initialization voltage, the initialization power line being electrically connected to the pixel circuit; and
an additional line disposed between the third sub-pixel and the fourth sub-pixel, the additional line being electrically connected to the initialization power line,
wherein, in a plan view, the vertical dummy line is disposed between the first data line and the second data line, and the additional line is disposed between the third data line and the fourth data line, and
wherein the vertical dummy line and the readout line are disposed in a same layer.

17. The display device of claim 16, wherein the vertical dummy line is electrically connected to the initialization power line, and is electrically separated from the horizontal dummy line.

18. The display device of claim 16, wherein the vertical dummy line is electrically connected to the horizontal dummy line, and is electrically separated from the initialization power line.

19. An electronic device comprising:
a processor which provides input image data; and
a display device which receives the input image data and displays an image, based on the input image data, the display device including:
a first sub-pixel and a second sub-pixel, each including a pixel circuit;
a light-sensing pixel disposed between the first sub-pixel and the second sub-pixel, the light-sensing pixel including a sensor circuit;
a horizontal dummy line commonly provided in the first sub-pixel, the second sub-pixel, and the light-sensing pixel, the horizontal dummy line extending in a first direction;
a first data line electrically connected to the first sub-pixel;
a second data line electrically connected to the second sub-pixel;
a readout line electrically connected to the sensor circuit, the readout line extending in a second direction;
a vertical dummy line spaced apart from the readout line; and
an initialization power line supplied with an initialization power voltage, the initialization power line being electrically connected to the pixel circuit,
wherein the readout line and the vertical dummy line are disposed in a same layer, and
wherein the first and second data lines are disposed on the readout line and the vertical dummy line.

20. The electronic device of claim 19, wherein, in a plan view, the readout line and the vertical dummy line are disposed between the first data line and the second data line.
